(19) United States
(12) Patent Application Publication
(10) Pub. No.: US 2026/0101710 A1
(43) Pub. Date: Apr. 9, 2026

(54) SUBSTRATE PROCESSING APPARATUS

(71) Applicant: SCREEN Holdings Co., Ltd., Kyoto (JP)

(72) Inventor: Ichiro MITSUYOSHI, Kyoto (JP)

(21) Appl. No.: 19/112,590

(22) PCT Filed: Jul. 25, 2023
(86) PCT No.: PCT/JP2023/027231

§ 371 Date: Mar. 17, 2025

(30) Foreign Application Priority Data
Sep. 22, 2022 (JP) 2022-151706

(51) Int. Cl. H10P 72/30; H10P 72/00

(52) U.S. Cl. CPC H10P 72/3412; H10P 72/0464; H10P 72/3211; H10P 72/3304

(57) ABSTRACT

A substrate processing apparatus includes a transfer block, a processing block, and a buffering unit. The transfer block includes a bulk transporting mechanism that stores substrates into a carrier, and a first orientation converting mechanism that converts the substrates into a vertical orientation. The processing block includes a batch processing area, a single-wafer processing area, a single-wafer transporting area, and a batch substrate transporting area. In the batch processing area, batch processing baths and a second orientation converting mechanism for converting the substrates into a horizontal orientation are provided. In the single-wafer processing area, for example, a single-wafer processing chamber is provided. In the single-wafer transporting area, a center robot-ER is provided. In the batch substrate transporting area, a first transporting mechanism is provided. The bulk transporting mechanism-HER transports the substrates to the first orientation converting mechanism IS, and transports the substrates from the buffering unit.

### TECHNICAL FIELD

The present invention relates to a substrate processing apparatus for processing a substrate. Examples of the substrate include a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### BACKGROUND ART

As a conventional substrate processing apparatus, there is a hybrid substrate processing apparatus including a batch processing module (batch processing unit) that processes a plurality of substrates as a batch, and a single-wafer processing module (single-wafer processing unit) that processes each one of the substrates having been processed by the batch processing module one by one (see, for example, Patent Literatures 1 and 2).

The substrate processing apparatus according to Patent Literature 1 includes: a loading port used for receiving a cassette; a first robot; two rotating mechanisms for rotating a wafer to and from a vertical orientation from and to a horizontal orientation; two baths arranged in a row between the two rotating mechanisms; a second robot capable of transporting a vertically-orientated wafer between the two rotating mechanisms and the two baths; a plurality of single-wafer cleaning modules performing cleaning and drying; and a third robot.

The plurality of single-wafer cleaning modules are arranged in a row. The first robot takes out five wafers at a time from a cassette, and transports the five wafers to the first rotating mechanism. The third robot takes out a wafer from the second rotating mechanism, and transports the wafer to the single-wafer cleaning module. The first robot takes out one wafer from one of the plurality of single-wafer cleaning modules, and returns the wafer into the cassette.

The substrate processing apparatus according to Patent Literature 2 includes a loading/unloading unit having a cassette placing table; a single-wafer processing unit (area); an interface unit; and a batch processing unit (area). The substrate processing apparatus according to Patent Literature 3 includes an orientation converting mechanism.

### CITATION LIST

### Patent Literature

Patent Literature 1: JP 2016-502275 A
Patent Literature 2: JP 2021-064652 A
Patent Literature 3: JP 2018-056341 A

### SUMMARY OF INVENTION

### Technical Problem

Such conventional substrate processing apparatuses have the following problems. For example, in the substrate processing apparatus according to Patent Literature 1, the first robot takes out five wafers as a batch from a cassette while moving along the plurality of single-wafer cleaning modules, and transports the five wafers to the first rotating mechanism. The first robot also takes out one wafer from one of the plurality of single-wafer cleaning modules while moving along the plurality of single-wafer cleaning modules, and returns the wafer to the cassette. Therefore, there is a possibility that the first robot is busy, and that the throughput of the substrate processing apparatus is deteriorated.

In addition, in the substrate processing apparatus according to Patent Literature 2, the loading/unloading unit, the single-wafer processing unit, the interface unit, and the batch processing unit are arranged in the order listed herein. Therefore, when the substrates are to be transported from the loading/unloading unit to the batch processing unit, the substrates need to be passed across the single-wafer processing unit. Therefore, the throughput of the substrate processing apparatus may deteriorate.

The present invention has been made in view of such circumstances, and an object of the present invention is to provide a substrate processing apparatus for improving the throughput.

### Solution to Problem

In order to achieve such an object, the present invention uses the following configurations. That is, a substrate processing apparatus according to the present invention is a substrate processing apparatus configured to perform a batch process in which a plurality of substrates are processed as a batch, and a single-wafer process in which one substrate is processed at a time, continuously, the substrate processing apparatus including: a stocker block; a transfer block that is positioned adjacently to the stocker block; a processing block that is positioned adjacently to the transfer block; and a substrate placing unit where a plurality of substrates in a horizontal orientation are placed along a vertical direction at a predetermined interval between the plurality of substrates, in which the stocker block that accommodates at least one carrier storing a plurality of substrates in the horizontal orientation at the predetermined interval between the plurality of substrates in a vertical direction, and includes at least one carrier placing shelf for taking out and storing a substrate, the carrier placing shelf on which the carrier is placed so as to enable a substrate to be taken out from or to be delivered to the carrier, the transfer block includes: a substrate handling mechanism that takes out or stores a plurality of substrates from and into the carrier placed in the carrier placing shelf, as a batch; and a first orientation converting mechanism that converts the plurality of substrates in the horizontal orientation to a vertical orientation, the processing block includes: a batch processing area extending in a direction separating from the transfer block; a single-wafer processing area having one end at a position near the transfer block and another end extending in the direction separating from the transfer block; a single-wafer transporting area interposed between the batch processing area and the single-wafer processing area, and having one end positioned adjacently to the transfer block and another end extending in the direction separating from the transfer block; and a batch substrate transporting area provided along the batch processing area, and having one end extending to the transfer block and another end extending in the direction separating from the transfer block, the batch processing area is provided with a plurality of batch processing baths that are configured to immerse a plurality of substrate as a batch, and that are arranged along a direction in which the batch processing area extends; and a second orientation converting mechanism that is configured to convert the plurality of substrates from the vertical orientation to the horizontal orientation, the single-wafer processing area is provided with a single-wafer processing chamber configured to process one substrate at a time, along the direction in which the single-wafer processing area extends, the single-wafer transporting area is provided with a single-wafer transporting mechanism that is configured to transport a substrate to and from the second orientation converting mechanism, the single-wafer processing chamber, and the substrate placing unit, the batch substrate transporting area is provided with a batch substrate transporting mechanism configured to transport a plurality of substrates to and from a substrate delivery position defined in the transfer block, the plurality of batch processing baths, and the second orientation converting mechanism, as a batch, and the substrate handling mechanism in the transfer block is configured to transport a plurality of substrates to the first orientation converting mechanism, as a batch, and transport a plurality of substrates from the substrate placing unit, as a batch.

With the substrate processing apparatus according to the present invention, the batch processing area, the single-wafer processing area, and the single-wafer transporting area are provided in a manner extending from the side of the transfer block. The plurality of batch processing baths are arranged along a direction in which the batch processing area extends. The plurality of single-wafer processing chambers are arranged along a direction in which the single-wafer processing area extends. The single-wafer transporting mechanism is provided in a single-wafer transporting area that is disposed between the plurality of batch processing baths and the plurality of single-wafer processing chambers. The batch substrate transporting mechanism is provided in the batch substrate transporting area, along the plurality of batch processing baths. Therefore, the substrate processing apparatus according to the present invention can transport substrates smoothly.

This operation will now be explained specifically. The substrate handling mechanism in the transfer block can take out a plurality of substrates from the carrier as a batch, and transport the plurality of substrates to the first orientation converting mechanism as a batch. The batch substrate transporting mechanism transports a plurality of substrates to and from the substrate passing position, the batch processing baths, and the second orientation converting mechanism. The single-wafer transporting mechanism transports the substrate to and from the second orientation converting mechanism, the single-wafer processing chamber, and the substrate placing unit. The substrate handling mechanism receives a plurality of substrates from the substrate placing unit as a batch, and house the plurality of substrates into the carrier as a batch.

Therefore, it is possible to transport the plurality of substrates directly from the transfer block to the batch processing area, without transporting the plurality of substrates to the single-wafer processing area before transporting the plurality of substrates to the batch substrate processing area. In addition, the substrate handling mechanism transports a plurality of substrates from and to the carrier, the first orientation converting mechanism, and the substrate placing unit as a batch, without accessing each of the single-wafer processing chambers. As a result, it is possible to transport a plurality of substrates quickly from the carrier to the first orientation converting mechanism, and to transport a plurality of substrates quickly from the substrate placing unit to the carrier. Hence, the substrate processing apparatus according to the present invention can transport substrates smoothly. Therefore, the throughput can be improved.

Furthermore, in the substrate processing apparatus described above, preferably, the second orientation converting mechanism is provided on an opposite side of the transfer block, with the plurality of batch processing baths disposed between the transfer block and the second orientation converting mechanism.

The plurality of substrates can be transported from the transfer block to the second orientation converting mechanism while performing a batch process in the batch processing baths, and then the plurality of substrates can be transported from the second orientation converting mechanism to the transfer block while performing a single-wafer process in the single-wafer processing chamber. In this manner, a plurality of substrates can be transported in a manner delineating a circle within the processing block, so that the substrates can be transported smoothly.

In the substrate processing apparatus described above, preferably, the second orientation converting mechanism is provided between two batch processing baths among the plurality of batch processing baths.

Because the second orientation converting mechanism is provided between the two batch processing baths, it is possible to ensure relatively uniform distances between the second orientation converting mechanism and the single-wafer processing chambers. Therefore, the single-wafer transporting mechanism can transport the substrates, around the center of the single-wafer transporting area as a base point. Therefore, the distance by which the single-wafer transporting mechanism is moved can be kept short, so that the efficiency of transporting the substrates can be improved.

In the substrate processing apparatus described above, preferably, the second orientation converting mechanism is provided between the transfer block and the plurality of batch processing baths. In this manner, the second orientation converting mechanism is positioned near the transfer block. Therefore, the substrates can be transported using the side of the transfer block as the base point.

Furthermore, in the substrate processing apparatus described above, preferably, the substrate placing unit is provided in a manner fixed at any one of a boundary between the transfer block and the single-wafer transporting area, in the transfer block, and in the single-wafer transporting area. Because the substrate placing unit is provided at a fixed position without moving, it is possible to simplify the configuration of the substrate placing unit and elements therearound.

Preferably, the substrate processing apparatus further includes a placing unit moving mechanism, the substrate placing unit is provided movably in the single-wafer transporting area, and the placing unit moving mechanism moves the substrate placing unit in a direction in which the single-wafer transporting area extends. Because the placing unit is moved by the placing unit moving mechanism, it is not necessary for the single-wafer transporting mechanism to move near the substrate handling mechanism. Therefore, the efficiency of transporting the substrates can be improved.

Furthermore, in the substrate processing apparatus described above, preferably, the placing unit moving mechanism moves the substrate placing unit in the direction in which the single-wafer transporting area extends, in a manner following the single-wafer transporting mechanism. Because the substrate placing unit is moved in a manner following the single-wafer transporting mechanism, the single-wafer transporting mechanism can transport substrates to the substrate placing unit, quickly.

Furthermore, in the substrate processing apparatus described above, preferably, the single-wafer transporting mechanism includes a mechanism main unit and an upper rail provided above the single-wafer transporting area and along the single-wafer transporting area, and the mechanism main unit is suspended from the upper rail and is configured to move along the upper rail. The mechanism main unit (e.g., an advancing/retracting unit and a rotating lift) is prevented from being contaminated with droplets dripping from a wet substrate. For example, when the mechanism main unit is contaminated with droplets, the single-wafer transporting mechanism may fail, but such a failure can be avoided.

Furthermore, in the substrate processing apparatus described above, the second orientation converting mechanism preferably includes a substrate holding unit that holds the plurality of substrates in the vertical orientation transported by the batch substrate transporting mechanism; a substrate extracting mechanism capable of extracting two or more substrates from the plurality of substrates held by the substrate holding unit; and an orientation converting unit that converts an orientation of the two or more substrates extracted by the substrate extracting mechanism from the vertical orientation to the horizontal orientation as a batch. With this, the orientation converting unit can convert the orientation of two or more substrates extracted by the substrate extracting mechanism.

### Advantageous Effect of Invention

With the substrate processing apparatus according to the present invention, it is possible to improve the throughput.

### BRIEF DESCRIPTION OF DRAWINGS

FIG. 1 is a plan view illustrating a schematic configuration of a substrate processing apparatus according to a first embodiment.

FIG. 2 is a side view illustrating a bulk transporting mechanism.

FIG. 3(a) to 3(f) are side views for explaining an orientation converting unit and a pusher mechanism included in a transfer block.

FIG. 4(a) is a plan view illustrating a second orientation converting mechanism, and FIG. 4(b) is a front view illustrating the second orientation converting mechanism.

FIG. 5 is a side view for explaining a second transporting mechanism and an orientation converting unit.

FIG. 6(a) is a plan view illustrating an auxiliary chuck opening/closing unit included in the orientation converting unit, and FIG. 6(b) is a side view illustrating an advancing/retracting unit included in the orientation converting unit.

FIG. 7(a) and 7(b) are schematics for explaining the operation of the advancing/retracting unit of the orientation converting unit.

FIG. 8 is a flowchart for explaining an operation of the substrate processing apparatus.

FIG. 9 is a flowchart for explaining a former half of an operation of the second orientation converting mechanism.

FIG. 10 is a flowchart for explaining a latter half of the operation of the second orientation converting mechanism.

FIG. 11(a) to 11(d) are plan views for explaining the operation of the second orientation converting mechanism.

FIG. 12(a) to 12(d) are front views for explaining the operation of the second orientation converting mechanism.

FIG. 13(a) and 13(b) are plan views for explaining the operation of the second orientation converting mechanism, and FIG. 13(c) and 13(d) are front views for explaining the operation of the second orientation converting mechanism.

FIG. 14(a) is a vertical sectional view illustrating a pusher mechanism included in a second orientation converting mechanism according to a second embodiment, and FIG. 14(b) is a plan view illustrating the second orientation converting mechanism according to the second embodiment.

FIG. 15 is a plan view illustrating a schematic configuration of a substrate processing apparatus according to a third embodiment.

FIG. 16(a) and 16(b) are side views for explaining a buffering unit according to the third embodiment.

FIG. 17 is a plan view illustrating a schematic configuration of a substrate processing apparatus according to a fourth embodiment.

FIG. 18 is a plan view illustrating a schematic configuration of a substrate processing apparatus according to a fifth embodiment.

FIG. 19 is a plan view illustrating a schematic configuration of a substrate processing apparatus according to a modification.

FIG. 20 is a side view illustrating a ceiling-suspended center robot according to a modification.

### FIRST EMBODIMENT

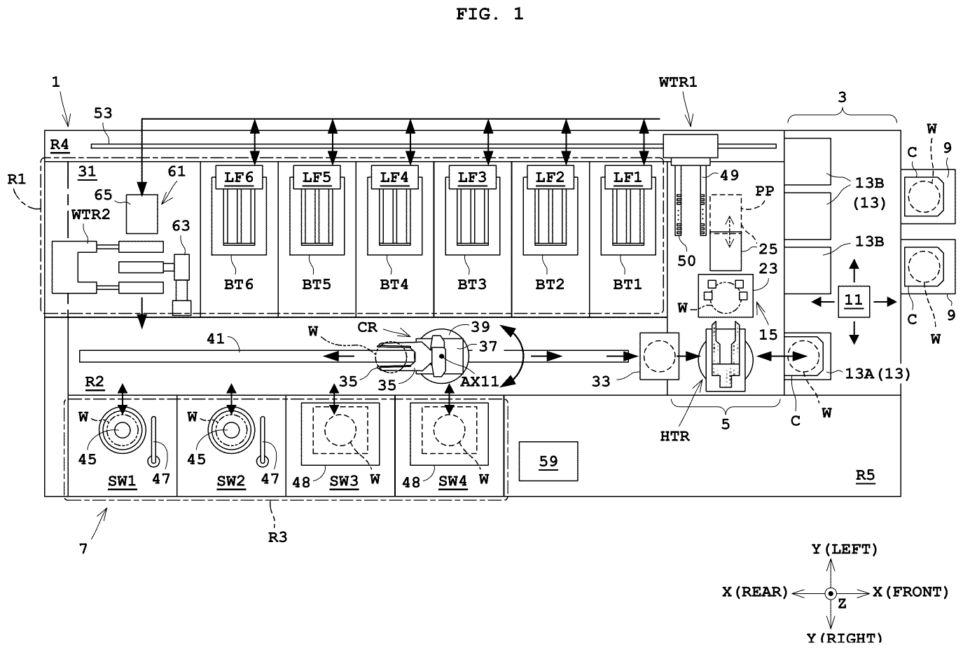

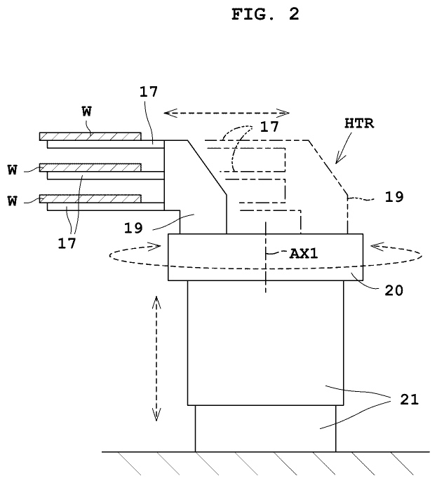

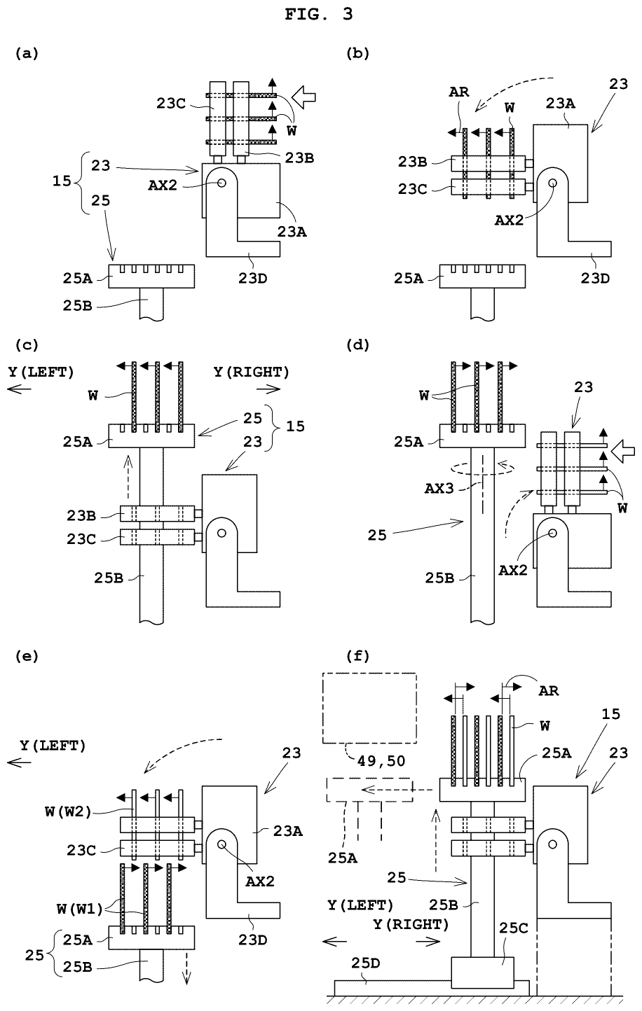

A first embodiment of the present invention will now be described with reference to drawings. FIG. 1 is a plan view illustrating a schematic configuration of a substrate processing apparatus 1 according to the first embodiment. FIG. 2 is a side view illustrating a bulk transporting mechanism HTR. FIG. 3(a) to 3(f) are side views for explaining an orientation converting unit and a pusher mechanism included in a transfer block.

### 1. Overall Configuration

FIG. 1 will now be referred to. The substrate processing apparatus 1 includes a stocker block 3, a transfer block 5, and a processing block 7. The stocker block 3, the transfer block 5, and the processing block 7 are arranged in a row along the horizontal direction in the order listed herein.

The substrate processing apparatus 1 performs processes such as a chemical liquid process, a cleaning process, and a drying process on the substrates W. The substrate processing apparatus 1 performs a batch process and a single-wafer process to the substrate W, continuously. That is, the substrate processing apparatus 1 performs a batch process and then performs a single-wafer process on the substrate W. The batch process is a processing method for processing a plurality of substrates W as a batch. The single-wafer process is a processing method for processing one substrates W at a time.

In the present specification, for convenience, a direction in which the stocker block 3, the transfer block 5, and the processing block 7 are arranged will be referred to as a “front-back direction X”. The front-back direction X is horizontal. Of the front-back direction X, the direction from the transfer block 5 toward the stocker block 3 will be referred to as “frontwards”. The direction opposite to the frontward direction will be referred to as “rearwards”. The horizontal direction orthogonal to the front-back direction X will be referred to as “width directions Y”. One of the width directions Y will be referred to as “rightwards”, as appropriate. The direction opposite to the rightward direction will be referred to as “leftwards”. The direction perpendicular to the horizontal directions will be referred to as “vertical directions Z”. In FIG. 1, for example, front, rear, right, left, top, and bottom are indicated as appropriate, for reference.

### 2. Stocker Block

The stocker block 3 accommodates at least one carrier C. One, or two or more (e.g., two) loading ports 9 are provided to the stocker block 3. The stocker block 3 includes a carrier transporting mechanism (robot) 11 and shelves 13.

The carrier transporting mechanism 11 transports the carrier C between the loading port 9 and the shelves 13. The carrier transporting mechanism 11 includes a gripper that grips a protrusion provided to the top surface of the carrier C, or a hand that is kept in contact with the bottom surface of the carrier C to support the carrier C. The shelves 13 are classified into a shelf 13A for taking in and out the substrate W, and a shelf 13B for storage.

The shelf 13A is positioned adjacently to the transfer block 5. The shelf 13A may have a mechanism for attaching and detaching a lid to and from the carrier C. The shelves 13 include at least one shelf 13A. On the shelf 13A, a carrier C is placed. The carrier C stores therein a plurality of (e.g., twenty-five) substrates W in the horizontal orientation, at a predetermined interval therebetween (e.g., an interval of 10 mm) in the vertical direction Z. The substrates W are aligned in the thickness direction of the substrates W. As one example of the carrier C, a front opening unify pod (FOUP) is used. The FOUP is a sealed container. The carrier C may also be any type of container including an open container. The shelf 13A corresponds to a carrier placing shelf according to the present invention.

### 3. Transfer Block

The transfer block 5 is positioned adjacently to and on the rear side X of the stocker block 3. The transfer block 5 includes a bulk transporting mechanism (robot) HTR, and a first orientation converting mechanism 15. The bulk transporting mechanism HTR corresponds to a substrate handling mechanism according to the present invention.

The bulk transporting mechanism HTR is positioned on the right side Y in the transfer block 5. The bulk transporting mechanism HTR transports a plurality of (e.g., twenty-five) substrates W in the horizontal orientation as a batch. The bulk transporting mechanism HTR takes out and stores the plurality of substrates W from and to the carrier C placed on the shelf 13A as a batch. The bulk transporting mechanism HTR is also configured to deliver a plurality of substrates W to and from the first orientation converting mechanism 15 and to and from a buffering unit 33, to be described later. In other words, the bulk transporting mechanism HTR can transport the plurality of substrates W in the horizontal orientation to and from the carrier C placed on the shelf 13A, the first orientation converting mechanism 15, and the buffering unit 33.

FIG. 2 will now be referred to. The bulk transporting mechanism HTR has a plurality of (e.g., twenty-five) hands 17. In FIG. 2, for the convenience of illustration, the bulk transporting mechanism HTR includes three hands 17. Each of the hands 17 holds one substrate W.

The bulk transporting mechanism HTR further includes a hand support 19, an advancing/retracting unit 20, and a rotating lift 21. The hand support 19 supports the plurality of hands 17. With this, the plurality of hands 17 move integrally. The advancing/retracting unit 20 advances and retracts the plurality of hands 17 by moving the hand support 19. The rotating lift 21 rotates the plurality of hands 17 and the like about a vertical axis AX1 by rotating the advancing/retracting unit 20 about the vertical axis AX1. Furthermore, the rotating lift 21 raises and lowers the plurality of hands 17 and the like by raising and lowering the advancing/retracting unit 20. The rotating lift 21 is fixed to a floor surface. That is, the rotating lift 21 does not move in the horizontal direction. Each of the advancing/retracting unit 20 and the rotating lift 21 includes an electric motor. The bulk transporting mechanism HTR may also have a hand (not illustrated) for transporting one substrate W, separately from the hands 17 and the hand support 19.

FIG. 1 will now be referred to. The first orientation converting mechanism 15 converts the orientation of the plurality of substrates W from the horizontal orientation to the vertical orientation as a batch. The first orientation converting mechanism 15 includes an orientation converting unit 23 and a pusher mechanism 25. In FIG. 1, the bulk transporting mechanism HTR, the orientation converting unit 23, and the pusher mechanism 25 are arranged toward the left side Y in the order listed herein. FIG. 3(a) to 3(f) are views for explaining the first orientation converting mechanism 15.

As illustrated in FIGS. 1 and 3(a), the orientation converting unit 23 includes a support base 23A, a pair of horizontal holders 23B, a pair of vertical holders 23C, and a rotation driving unit 23D. The pair of horizontal holders 23B and the pair of vertical holders 23C are provided on the support base 23A. The horizontal holders 23B and the vertical holders 23C receive the plurality of substrates W transported by the bulk transporting mechanism HTR. While the substrates W are in the horizontal orientation, the pair of horizontal holders 23B supports the substrates W from the bottom, in a manner in contact with the bottom surfaces of the respective substrates W. While the substrates W are in the vertical orientations, the pair of vertical holders 23C hold the substrates W.

The rotation driving unit 23D rotatably supports the support base 23A about a horizontal axis AX2. The rotation driving unit 23D also converts the orientation of the plurality of substrates W held by the holders 23B, 23C from a horizontal orientation to the vertical orientation, by rotating the support base 23A about the horizontal axis AX2.

As illustrated in FIGS. 1 and 3(f), the pusher mechanism 25 includes a pusher 25A, a rotating lift 25B, a horizontally moving unit 25C, and a rail 25D. The pusher 25A supports the lower part of each of a plurality of (e.g., fifty) vertically oriented substrates W. In FIG. 3(a) to 3(f), the pusher 25A is enabled to support six substrates W, for the convenience of illustration.

The rotating lift 25B is connected to the bottom surface of the pusher 25A. The rotating lift 25B extends and contracts so as to raise and to lower the pusher 25A in up-and-down directions. The rotating lift 25B also rotates the pusher 25A about a vertical axis AX3. The horizontally moving unit 25C supports the rotating lift 25B. The horizontally moving unit 25C moves the pusher 25A and the rotating lift 25B horizontally, along the rail 25D. The rail 25D is provided in a manner extending in the width direction Y. Each of the rotation driving unit 23D, the rotating lift 25B, and the horizontally moving unit 25C has an electric motor.

An operation of the first orientation converting mechanism 15 will now be described. Batch processing baths BT1 to BT6, to be described later, in the processing block 7 processes, for example, fifty substrates W corresponding to two carriers C as a batch. The first orientation converting mechanism 15 converts the orientation of fifty substrates W in units of twenty-five. The first orientation converting mechanism 15 also arranges the plurality of substrates W face-to-face at a predetermined interval (half pitch). The half pitch is, for example, an interval of 5 mm. The pusher mechanism 25 transports the fifty substrates W to a first transporting mechanism WTR1.

The twenty-five substrates W in the first carrier C will be described as substrates W1 of a first substrate group. The twenty-five substrates W in the second carrier C will be described as substrates W2 of a second substrate group. Furthermore, in FIG. 3(a) to 3(f), for the convenience of illustration, a description will be made assuming that the number of substrates W1 in the first substrate group is three and the number of substrates W2 in the second substrate group is three. When the substrates W1 and the substrates W2 are not particularly distinguished from each other, the substrates W1 and W2 will be referred to as “substrates W”.

FIG. 3(a) will now be referred to. The orientation converting unit 23 causes the holders 23B, 23C to receive the twenty-five substrates W1 of the first substrate group, having been transported by the bulk transporting mechanism HTR. At this time, the twenty-five substrates W1 are in the horizontal orientation, with their device surfaces facing upwards. The twenty-five substrates W1 are arranged at a predetermined interval (full pitch). The full pitch is, for example, an interval of 10 mm. The full pitch will be sometimes referred to as a normal pitch.

Note that the half pitch is an interval corresponding to a half of the full pitch. The device surface of the substrate W (W1, W2) is a surface on which an electronic circuit is formed, and will be referred to as a “front surface”. The surface of the substrate W without any electronic circuit will be referred to as a rear surface. The surface on the opposite side of the device surface is the rear surface.

FIG. 3(b) will now be referred to. The orientation converting unit 23 rotates the pair of horizontal holders 23B, 23C by 90 degrees about the horizontal axis AX2, to convert the orientation of the twenty-five substrates W1 from the horizontal to the vertical. FIG. 3(c) will now be referred to. The pusher mechanism 25 raises the pusher 25A to a position higher than the holders 23B, 23C in the orientation converting unit 23. The pusher 25A then receives twenty-five substrates W from the holders 23B, 23C. The twenty-five substrates W1 held on the pusher 25A face the left side Y. In FIG. 3(a) to 3(f), the arrow AR given to the substrate W indicates the direction of the device surface of the substrate W.

FIG. 3(d) will now be referred to. The pusher mechanism 25 also rotates the twenty-five substrates W by 180 degrees about the vertical axis AX3. As a result, the twenty-five substrates W1 are reversed and come to face the right side Y. Further, the positions of twenty-five reversed substrates W1 are shifted leftwards Y by a half pitch (e.g., 5 mm) from the position prior to the rotation. The holders 23B, 23C of the orientation converting unit 23 are also rotated by −90 degrees about the horizontal axis AX2 so that the next substrates W2 can be received. The orientation converting unit 23 causes the holders 23B, 23C to receive the twenty-five substrates W2 of the second substrate group, having been transported by the bulk transporting mechanism HTR. At this time, the twenty-five substrates W2 are in the horizontal orientation, with their device surfaces facing upwards. The orientation converting unit 23 and the pusher mechanism 25 are operated so as not to interfere with each other.

FIG. 3(e) will now be referred to. The pusher mechanism 25 lowers the pusher 25A holding the twenty-five substrates W1 of the first substrate group to the retracted position. The orientation converting unit 23 then converts the orientation of the twenty-five substrates W2 from the horizontal to the vertical. The twenty-five substrates W2 after the orientation conversion comes to face the left side Y. FIG. 3(f) will now be referred to. The pusher mechanism 25 then raises the pusher 25 A holding the twenty-five substrates W2 of the second substrate group. With this, the pusher mechanism 25 receives the additional twenty-five substrates W2 from the orientation converting unit 23.

As a result, the pusher 25A comes to hold fifty substrates W (W1, W2) belonging to the first substrate group and the second substrate group. In the fifty substrates W, each one of the twenty-five substrates W1 and the twenty-five substrates W2 is positioned alternately. The fifty substrates W are arranged at a half pitch (e.g., at an interval of 5 mm). The twenty-five substrates W1 face in the direction opposite to the direction to which the twenty-five substrates W2 face. Thus, the fifty substrates W are arranged face-to-face. That is, two device surfaces (or two rear surfaces) of two adjacent substrates W1, W2 face each other.

The pusher mechanism 25 then moves the pusher 25A holding the fifty substrates W along the rail 25D, to the substrate delivery position PP below a pair of chucks 49, 50 of the first transporting mechanism WTR1.

### 4. Processing Block 7

The processing block 7 is positioned adjacently to the transfer block 5. The processing block 7 is disposed on the rear side X of the transfer block 5. The processing block 7 includes a batch processing area R1, a single-wafer transporting area R2, a single-wafer processing area R3, and a batch substrate transporting area R4. The substrate processing apparatus 1 includes an electrical equipment area R5.

### <4-1. Batch Processing Area R1>

The batch processing area R1 is positioned adjacently to the transfer block 5, the single-wafer transporting area R2, and the batch substrate transporting area R4. The batch processing area R1 is disposed between the single-wafer transporting area R2 and the batch substrate transporting area R4. One end of the batch processing area R1 is positioned adjacently to the transfer block 5, and the other end of the batch processing area R1 extends in a direction separating from the transfer block 5, that is, rearwards X.

In the batch processing area R1, six batch processing baths BT1 to BT6 and a second orientation converting mechanism 31 are provided, for example. The six batch processing baths BT1 to BT6 are arranged in a row in the front-back direction X in which the batch processing area R1 extends. The second orientation converting mechanism 31 is disposed on the opposite side of the transfer block 5 with the six batch processing baths BT1 to BT6 interposed therebetween. That is, the six batch processing baths BT1 to BT6 are disposed between the transfer block 5 and the second orientation converting mechanism 31. The second orientation converting mechanism 31 (pusher mechanism 61) is disposed on a line extended from the row of the six batch processing baths BT1 to BT6. The number of batch processing baths is not limited to six, and may be any number more than one.

In each of the six batch processing baths BT1 to BT6, a plurality of substrates W are immersed as a batch. The six batch processing baths BT1 to BT6 include, for example, four chemical liquid processing baths BT1 to BT4 and two water cleaning processing baths BT5, BT6. Specifically, the two chemical liquid processing baths BT1, BT2 and the water cleaning processing bath BT5 constitute one set. The two chemical liquid processing baths BT3, BT4 and the water cleaning processing bath BT6 constitute another set.

Each of the four chemical liquid processing baths BT1 to BT4 performs an etching process using a chemical liquid. As the chemical liquid, for example, phosphoric acid is used. The chemical liquid processing bath BT1 stores therein a chemical liquid supplied from a chemical liquid ejection pipe, not illustrated. The chemical liquid ejection pipe is provided on the inner wall of the chemical liquid processing bath BT1. Each of the three chemical liquid processing baths BT2 to BT4 has the same configuration as the chemical liquid processing bath BT1.

Each of the two water cleaning processing baths BT5, BT6 performs a pure water cleaning process, for cleaning the chemical liquid attached to the plurality of substrates W with pure water. As the pure water, deionized water (DIW) is used, for example. Each of the two water cleaning processing baths BT5, BT6 stores therein pure water supplied from a cleaning liquid ejection pipe, not illustrated. The cleaning liquid ejection pipe is provided on the inner wall of each of the water cleaning processing baths BT5, BT6.

The six batch processing baths BT1 to BT6 are provided with six lifters LF1 to LF6, respectively. For example, the lifter LF1 holds a plurality of vertically oriented substrates W that are arranged at a predetermined interval (half pitch). The lifter LF1 then raises and lowers the plurality of substrates W to and from a processing position inside the batch processing bath BT1 and a delivery position above the batch processing bath BT1 (chemical liquid processing bath). The other five lifters LF2 to LF6 have the same configurations as the lifter LF1.

The second orientation converting mechanism 31 converts the orientation of the plurality of substrates W from the vertical to the horizontal, as a batch. The second orientation converting mechanism 31 will be described later in detail.

### <4-2. Single-Wafer Transporting Area R2>

The single-wafer transporting area R2 is positioned adjacently to the transfer block 5, the batch processing area R1, the single-wafer processing area R3, and the electrical equipment area R5. The single-wafer transporting area R2 is interposed between the batch processing area R1 and the single-wafer processing area R3. One end of the single-wafer transporting area R2 is positioned adjacently to the transfer block 5. The other end of the single-wafer transporting area R2 extends in a direction separating from the transfer block 5, that is, rearwards X.

A center robot CR and a buffering unit 33 are provided in the single-wafer transporting area R2. The center robot CR transports the substrates between the second orientation converting mechanism 31, the single-wafer processing chambers SW1 to SW4, which will be described later, and the buffering unit 33. The center robot CR includes two hands 35, an advancing/retracting unit 37, a rotating lift 39, and a horizontally moving unit 41 (including a guide rail).

Each of the two hands 35 holds one substrate W in the horizontal orientation. The advancing/retracting unit 37 movably supports the hands 35, and advances and retracts the hands 35, individually. The rotating lift 39 rotates the hands 35 and the advancing/retracting unit 37 about a vertical axis AX11. The rotating lift 39 raises and lowers the hands 35 and the advancing/retracting unit 37. The guide rail is provided along the direction in which the single-wafer transporting area R2 extends, and is provided on the floor surface of the single-wafer transporting area R2. The horizontally moving unit 41 moves the hands 35, the advancing/retracting unit 37, and the like in the front-back direction X along the guide rail. Each one of the advancing/retracting unit 37, the rotating lift 39, and the horizontally moving unit 41 includes an electric motor.

For example, the advancing/retracting unit 37 advances the two hands 35 to take out two substrates W from the second orientation converting mechanism 31. The advancing/retracting unit 37 may then advance one of the hands 35 holding one substrate W to transport the one substrate W to one of the single-wafer processing chambers. The center robot CR may include one, or three or more hands 35. When three or more hands 35 are provided, the center robot CR moves three or more hands 35 back and forth individually.

The buffering unit 33 includes a plurality of placing shelves. Each of the plurality of placing shelves is in a horizontal orientation. On each of the plurality of placing shelves, one substrate W can be placed.

The buffering unit 33 places a plurality of substrates W in the horizontal orientation, with a predetermined interval (full pitch) therebetween in the vertical direction Z. That is, the plurality of placing shelves are arranged at a predetermined interval (full pitch) in the vertical direction Z. The buffering unit 33 is configured in such a manner that at least twenty-five substrates W that can be transported by the bulk transporting mechanism HTR can be placed, for example. For example, the buffering unit 33 is enabled to place fifty substrates W thereon.

As illustrated in FIG. 1, specifically, the buffering unit 33 is disposed in a manner straddling across the transfer block 5 and the single-wafer transporting area R2. That is, the buffering unit 33 is provided at the boundary between the transfer block 5 and the single-wafer transporting area R2. The buffering unit 33 may also be provided only in the transfer block 5 or the single-wafer transporting area R2. That is to say, the buffering unit 33 may be provided in a manner fixed at any one of the boundary between the transfer block 5 and the single-wafer transporting area R2, in the transfer block 5, and in the single-wafer transporting area R2. Because the buffering unit 33 is provided at a fixed position without moving, it is possible to simplify the configuration of the buffering unit 33 and elements therearound.

The buffering unit 33 corresponds to a substrate placing unit according to the present invention. The center robot CR corresponds to a single-wafer transporting mechanism according to the present invention.

### <4-3. Single-Wafer Processing Area R3>

The single-wafer processing area R3 is positioned adjacently to the single-wafer transporting area R2 and the electrical equipment area R5. One end of the single-wafer processing area R3 is positioned near the transfer block 5 with the electrical equipment area R5 therebetween. In the electrical equipment area R5, electric circuits necessary for the substrate processing apparatus 1 and a control unit 59, which will be described later, are provided. The other end of the single-wafer processing area R3 extends in the direction separating from the transfer block 5, that is, rearwards X. The single-wafer processing area R3 is provided along the batch processing area R1 and the single-wafer transporting area R2.

In the single-wafer processing area R3, a plurality of (for example, four) single-wafer processing chambers SW1 to SW4 are provided. The four single-wafer processing chambers SW1 to SW4 are arranged in the front-back direction X in which the single-wafer processing area R3 extends. Each of the single-wafer processing chambers SW1 to SW4 processes one substrate W at a time. The first single-wafer processing chamber SW1 is disposed at a position farthest away from the transfer block 5. The second single-wafer processing chamber SW2 is disposed in front X of the first single-wafer processing chamber SW1. The third single-wafer processing chamber SW3 is disposed in front X of the second single-wafer processing chamber SW2. The fourth single-wafer processing chamber SW4 is disposed in front X of the third single-wafer processing chamber SW3. The single-wafer processing chambers SW1 to SW4 may include a plurality of levels. For example, twelve single-wafer processing chambers may be disposed in an arrangement of four by three in the front-back direction X (horizontal direction) and the vertical direction Z, respectively.

Each of the single-wafer processing chambers SW1, SW2 includes, for example, a rotating processing unit 45 and a nozzle 47. The rotating processing unit 45 includes a spin chuck that holds one horizontally oriented substrate W, and an electric motor that rotates the spin chuck about a vertical axis passing through the center of the substrate W. The spin chuck may hold the bottom surface of the substrate W by vacuum suctioning. The spin chuck may also include three or more chuck pins that grip the outer edge of the substrate W.

The nozzle 47 supplies a processing liquid onto the substrate W held by the rotating processing unit 45. The nozzle 47 is moved across a standby position away from the rotating processing unit 45 and a supply position above the rotating processing unit 45. As the processing liquid, for example, pure water (DIW) and isopropyl alcohol (IPA) are used. In each of the single-wafer processing chambers SW1, SW2, for example, the substrate W may be subjected to cleaning process with pure water, then preliminarily dried with IPA, or a liquid film of IPA may be formed on the top surface of the substrate W.

Each of the single-wafer processing chambers SW3, SW4 performs, for example, drying process that uses a supercritical fluid. As the fluid, carbon dioxide is used, for example. Each of the single-wafer processing chamber SW3, SW4 includes a chamber body (container) 48, a support tray, and a lid. The chamber body 48 has an internal processing space, an opening through which the substrate W is inserted into the processing space, a supply port, and an exhaust port. The substrate W is housed in the processing space, in a manner supported on the support tray. The lid closes the opening of the chamber body 48. For example, in each of the single-wafer processing chambers SW3, SW4, the fluid is changed to the supercritical state, and the supercritical fluid is supplied into the processing space of the chamber body 48 through the supply port. At this time, the air in the processing space of the chamber body 48 is exhausted from the exhaust port. With the supercritical fluid supplied to the processing space, the substrate W is subjected to the drying process.

The supercritical state is achieved by setting the fluid to the critical temperature and the critical pressure unique to the fluid. Specifically, when carbon dioxide is used as the fluid, the critical temperature is 31° C., and the critical pressure is 7.38 MPa. In the supercritical state, the surface tension of the fluid is almost zero. Therefore, the patterns on the substrates W are not affected by the gas-liquid interface. Hence, it is less likely for the substrate W to experience pattern collapses.

### <4-4. Batch Substrate Transporting Area R4>

The batch substrate transporting area R4 is positioned adjacently to the transfer block 5 and the batch processing area R1. The batch substrate transporting area R4 is provided along the batch processing area R1. The batch substrate transporting area R4 extends in the front-back direction X. The four areas R1, R2, R3, and R4 are provided in a manner extending in parallel with one another.

The batch substrate transporting area R4 includes the first transporting mechanism (robot) WTR1. In other words, in the batch substrate transporting area R4, the first transporting mechanism WTR1 is provided. The first transporting mechanism WTR1 transports a plurality of (e.g., fifty) substrates W as a batch, from and to the substrate delivery position PP defined in the transfer block 5, each of the six batch processing baths BT1 to BT6, for example, and the second orientation converting mechanism 31.

The first transporting mechanism WTR1 includes a pair of chucks 49, 50 and a guide rail 53. Each of the chucks 49, 50 includes, for example, fifty holding grooves for holding fifty substrates W. Each of the two chucks 49, 50 extends in parallel with the Y direction (FIG. 1) in plan view. The first transporting mechanism WTR1 opens and closes the two chucks 49, 50. The first transporting mechanism WTR1 moves the pair of chucks 49, 50 along the guide rail 53. The first transporting mechanism WTR1 is driven by an electric motor.

### 5. Control Unit

The substrate processing apparatus 1 includes a control unit 59 and a storage unit (not illustrated). The control unit 59 controls each component included in the substrate processing apparatus 1. The control unit 59 includes one or more processors such as a central processing unit (CPU). The storage unit includes at least one of a read-only memory (ROM), a random-access memory (RAM), and a hard disk, for example. The storage unit stores therein a computer program required in controlling each of the components included in the substrate processing apparatus 1.

### 6. Second Orientation Converting Mechanism

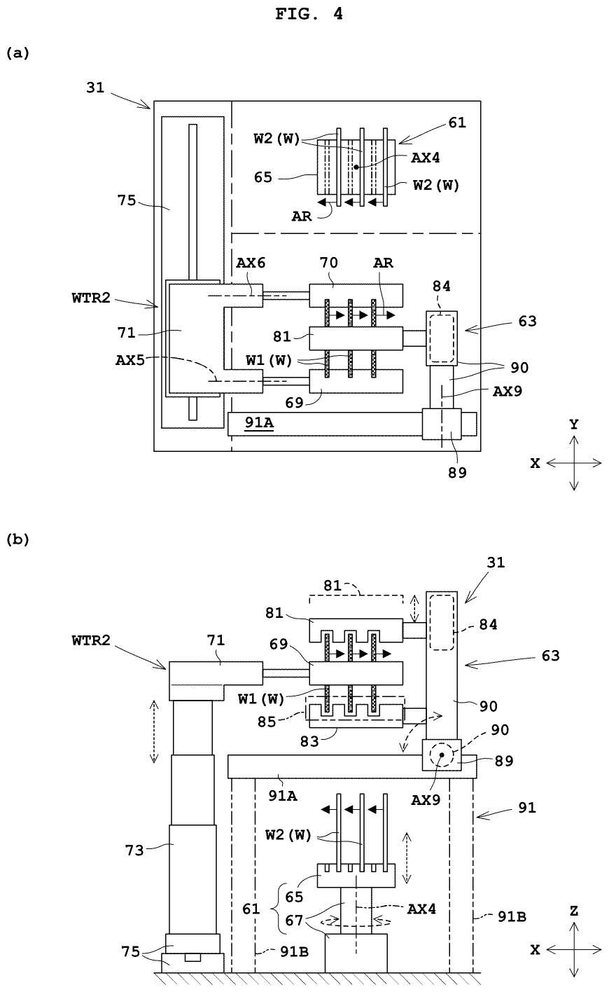

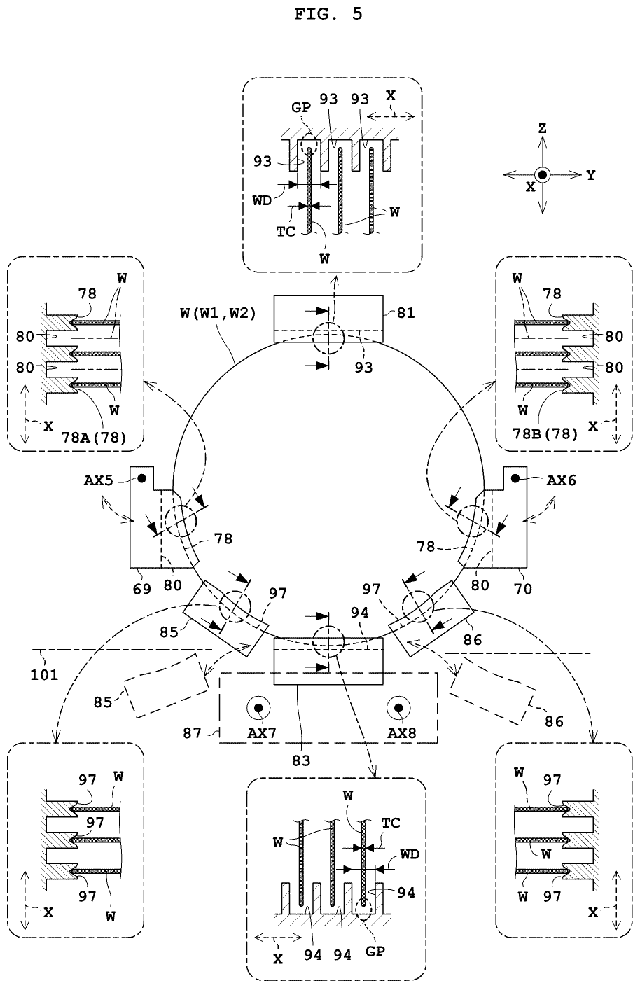

FIG. 4(a) is a plan view illustrating the second orientation converting mechanism 31. FIG. 4(b) is a front view illustrating the second orientation converting mechanism 31. FIG. 5 is a side view for explaining the second transporting mechanism WTR2 and an orientation converting unit 63. The second orientation converting mechanism 31 includes a pusher mechanism 61, a second transporting mechanism (second batch substrate transporting mechanism) WTR2, and the orientation converting unit 63. The second transporting mechanism WTR2 corresponds to a substrate extracting mechanism according to the present invention.

### <6-1. Pusher Mechanism>

The pusher mechanism 61 is configured to receive a plurality of substrates W from the first transporting mechanism WTR1. The pusher mechanism 61 can hold the plurality of substrates W in the vertical orientation, and rotate the plurality of substrates W about a vertical axis AX4. The pusher mechanism 61 includes a pusher 65 and a rotating lift 67.

The pusher 65 holds a plurality of substrates W in the vertical orientation, the plurality of substrates W having been transported by the first transporting mechanism WTR1 and arranged at a predetermined interval (e.g., half pitch). The rotating lift 67 raises and lowers the pusher 65, and rotates the pusher 65 about the vertical axis AX4. The rotating lift 67 includes, for example, one, or two or more electric motors. The pusher 65 corresponds to a substrate holding unit according to the present invention.

### <6-2. Second Batch Transporting Mechanism (Second Transporting Mechanism)>

The second transporting mechanism (robot) WTR2 takes out a plurality of substrates W from the pusher 65 and transports the substrates W. The second transporting mechanism WTR2 includes two chucks (horizontal chucks) 69, 70, an opening/closing unit 71, a lifting unit 73, and a horizontally moving unit 75. As illustrated in FIG. 5, the chucks 69, 70 hold a plurality of substrates W by radially nipping the two sides on the outer edge of each of the plurality of substrates W that are in the vertical orientation.

Each of the two chucks 69, 70 includes a plurality of (e.g., twenty-five) V-shaped holding grooves 78 and a plurality of (e.g., twenty-five) passing grooves 80. Each of the V-shaped holding grooves 78 and each of the passing grooves 80 are alternately arranged. The end of each of the V-shaped holding grooves 78 has a V-shape cross section. The V-shaped holding groove 78A of the chuck 69 faces the V-shaped holding groove 78B of the chuck 70. With this, one pair of the V-shaped holding grooves 78A, 78B holds one substrate W. The twenty-five pairs of V-shaped holding grooves 78 on the two chucks 69, 70 hold twenty-five substrates W in the vertical orientation, respectively.

The passing grooves 80 do not hold a substrate W. The V-shaped holding grooves 78 are arranged at a predetermined interval (e.g., full pitch). The passing grooves 80 are also arranged at the predetermined interval (e.g., full pitch). As a result, the second transporting mechanism WTR2 can extract every other substrates W from the plurality of substrates W that are arranged at the half pitch.

The opening/closing unit 71 illustrated in in FIG. 4(a) swings (rotates) the chuck 69 about a horizontal axis AX5, and swings the chuck 70 about a horizontal axis AX6. As a result, the opening/closing unit 71 enables the substrates W to be held by nipping, or enables the substrates W having been nipped to be released. When the substrates W are nipped between the pair of chucks 69, 70, the width between the two ends of the V-shaped holding grooves 78A, 78B becomes smaller than the diameter of the substrates W. The substrates W are thus held. Each of the two horizontal axes AX5 and AX6 extends in the front-back direction X in which the substrates W are aligned. The horizontal axis AX5 extends in parallel with the horizontal axis AX6.

The lifting unit 73 raises and lowers the chucks 69, 70 and the opening/closing unit 71. The horizontally moving unit 75 moves the chucks 69, 70 and the lifting unit 73 in the width direction Y (see FIG. 4(a)). The horizontally moving unit 75 moves the chucks 69, 70 between a position above the pusher 65 and a delivery position for making delivery to the orientation converting unit 63. Each of the opening/closing unit 71, the lifting unit 73, and the horizontally moving unit 75 includes, for example, an electric motor.

The upper ends of the chucks 69, 70 are preferably lower than the upper ends of the substrates W held thereby. In addition, the lower ends of the chucks 69, 70 are preferably higher than the lower ends of the substrates W held thereby. In this manner, the chucks 69, 70 holding the substrates W can be easily passed between an upper chuck 81 and a lower chuck 83, to be described later. Therefore, the chucks 69, 70 can smoothly deliver the substrate W to the upper and lower chucks 81, 83.

### <6-3. Orientation Converting Unit>

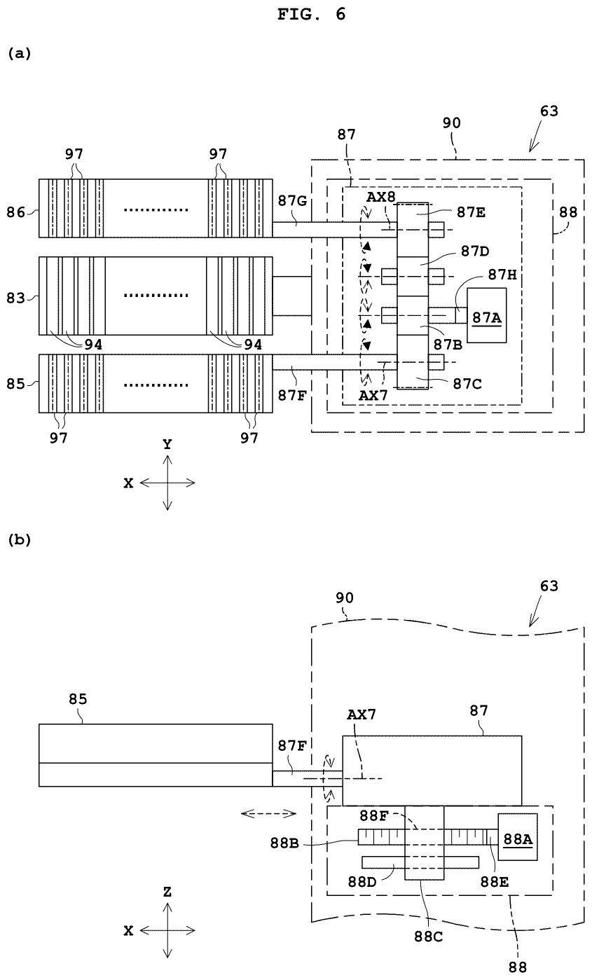

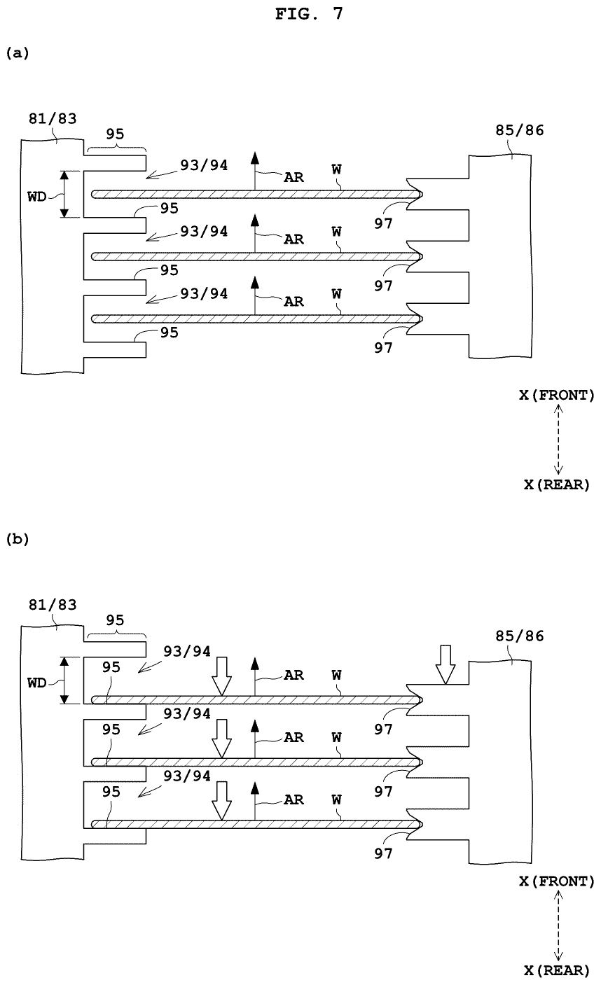

FIG. 6(a) is a plan view illustrating an auxiliary chuck opening/closing unit 87 in the orientation converting unit 63. FIG. 6(b) is a side view illustrating an advancing/retracting unit 88 in the orientation converting unit 63. FIG. 7(a) and 7(b) are schematics for explaining the operation of the advancing/retracting unit 88 of the orientation converting unit 63.

FIG. 4(a), 4(b), 6(a), and the like will now be referred to. The orientation converting unit 63 converts the orientation of the substrates W having been transported by the second transporting mechanism WTR2, from the vertical to the horizontal. The orientation converting unit 63 includes an upper chuck 81, a lower chuck 83, an upper chuck moving unit 84, two auxiliary chucks 85, 86, the auxiliary chuck opening/closing unit 87, the advancing/retracting unit 88, an upper and lower chuck rotating unit 89, a support arm 90, and a base frame 91.

The upper chuck 81 and the lower chuck 83 (hereinafter, referred to as “upper and lower chucks 81, 83” as appropriate) nip the upper part and the lower part of the outer edge of each of the plurality of substrates W in the vertical orientation held by the two chucks 69, 70, from the radial directions. In this manner, the upper chuck 81 and the lower chuck 83 can receive the substrate W directly from the two chucks 69, 70 of the second transporting mechanism WTR2.

The upper chuck 81 is provided on the support arm 90 in a vertically movable manner. The upper chuck moving unit 84 can move the upper chuck 81 nearer to the lower chuck 83, and also move the upper chuck 81 away from the lower chuck 83. The upper chuck moving unit 84 is provided to the support arm 90. The upper chuck moving unit 84 includes, for example, a linear actuator having an electric motor. The lower chuck 83 is not movable, and is fixed to the support arm 90.

As illustrated in FIG. 5, the upper chuck 81 includes a plurality of (e.g., twenty-five) first horizontal setting guide grooves 93. Similarly, the lower chuck 83 includes a plurality of (e.g., twenty-five) second horizontal setting guide grooves 94. For example, the twenty-five first horizontal setting guide grooves 93 are configured to house the outer edges of the twenty-five substrates W, respectively. The twenty-five second horizontal setting guide grooves 94 are configured to house the outer edges of the twenty-five substrates W, respectively. Each of the horizontal setting guide grooves 93, 94 has a setting surface 95 on which one substrate W is placed (see FIG. 7(a)).

Each of the horizontal setting guide grooves 93, 94 has a width WD larger than the thickness TC of each substrate W. That is, a width WD of each of the horizontal setting guide grooves 93, 94 from entrance to the rear end of the horizontal setting guide groove 93, 94 is wider than the thickness TC of each of the substrates W. In this manner, when the hands 35 of the center robot CR takes out one substrate W in the horizontal orientation from the horizontal setting guide groove 93, 94, the one substrate W in the horizontal orientation can be lifted within the horizontal setting guide groove 93, 94. That is, each of the horizontal setting guide grooves 93, 94 has a space in which the substrate W is freely movable.

In addition, a gap GP (space) for moving the substrate W in the radial directions of the substrate W is provided in the horizontal setting guide grooves 93, 94 when the substrates W are nipped by the upper chuck 81 and the lower chuck 83.

The auxiliary chucks 85, 86 hold the lower side of each substrate W. The two auxiliary chucks 85, 86 are provided on both sides of the lower chuck 83 along the circumferential direction of each of the substrates W. More specifically, referring to FIG. 5, when the two chucks 69, 70, the upper chuck 81, and the lower chuck 83 nip each substrate W, the first auxiliary chuck 85 is disposed between the chuck 69 and the lower chuck 83. The second auxiliary chuck 86 is disposed between the chuck 70 and the lower chuck 83.

Similarly to the chucks 69, 70, each of the two auxiliary chucks 85, 86 includes a plurality of (e.g., twenty-five) V-shaped holding grooves 97. The rear end of each of the holding grooves 97 has a V-shaped cross section.

When the upper chuck 81 and the lower chuck 83 hold the substrates W in the “vertical orientation”, each of the auxiliary chucks 85, 86 holds the substrates W in the vertical orientation by housing the outer edges of the respective substrates W in the V-shaped holding grooves 97, respectively. When the upper chuck 81 and the lower chuck 83 hold the substrates W in the “horizontal orientation”, each of the two auxiliary chucks 85, 86 releases the substrates W from the V-shaped holding grooves 97, and moves away from the substrates W to a position where the center robot CR taking out the substrate W is not obstructed.

The auxiliary chuck opening/closing unit 87 is provided to the support arm 90 via the advancing/retracting unit 88. The auxiliary chuck opening/closing unit 87 swings (rotates) the first auxiliary chuck 85 about a horizontal axis AX7, and swings the second auxiliary chuck 86 about a horizontal axis AX8. This will be described with reference to FIG. 6(a).

The auxiliary chuck opening/closing unit 87 includes, for example, an electric motor 87A, a first gear 87B, a second gear 87C, a third gear 87D, a fourth gear 87E, a first shaft 87F, and a second shaft 87G.

The first gear 87B is fixed to the output shaft 87H of the electric motor 87A. The second gear 87C is fixed to the first shaft 87F. The first shaft 87F is rotatably supported about the horizontal axis AX7. The first auxiliary chuck 85 is connected to the distal end of the first shaft 87F. The third gear 87D is rotatably supported about the horizontal axis. The fourth gear 87E is fixed to the second shaft 87G. The second shaft 87G is rotatably supported around the horizontal axis AX8. A second auxiliary chuck 86 is connected to the distal end of the second shaft 87G.

The two gears 87B and 87C mesh with each other. The two gears 87B and 87D mesh with each other. The two gears 87D and 87E also mesh with each other. When the electric motor 87A rotates the output shaft 87H forwardly, the auxiliary chucks 85, 86 are caused to hold the substrates W. By contrast, when the electric motor 87A rotates the output shaft 87H reversely, the auxiliary chucks 85, 86 are moved away from the substrate W, and releases the substrates W.

Each of the two horizontal axes AX7, AX8 extends in the front-back direction X in which the substrates W are aligned. The horizontal axis AX7 extends in parallel with the horizontal axis AX8. When the auxiliary chucks 85, 86 are not to hold the substrates W, the auxiliary chuck opening/closing unit 87 moves the pair of auxiliary chucks 85, 86 to the outside of the one-dot chain line 101, indicated by a broken line in FIG. 5.

As illustrated in FIG. 6(b), the advancing/retracting unit 88 is provided on the support arm 90. The advancing/retracting unit 88 moves (advances and retracts) the auxiliary chucks 85, 86 with respect to the upper and lower chucks 81, 83 in the front-back direction X in which the substrates W are aligned. The advancing/retracting unit 88 includes, for example, an electric motor 88A, a screw shaft 88B, a slider 88C, and a guide rail 88D.

An output shaft 88E of the electric motor 88A is connected to one end of the screw shaft 88B. The screw shaft 88B is passed through the slider 88C, in a manner meshed with a nut portion 88F of the slider 88C.

The guide rail 88D is passed through the slider 88C. The slider 88C is freely movable with respect to the guide rail 88D. The slider 88C is connected to the auxiliary chuck opening/closing unit 87. The screw shaft 88B and the guide rail 88D extend in the front-back direction X in which the substrates W are aligned. When the electric motor 88A rotates the output shaft 88E forwardly, the auxiliary chucks 85, 86 are advanced with respect to the upper and lower chucks 81, 83. By contrast, when the electric motor 88A rotates the output shaft 88E reversely, the auxiliary chucks 85, 86 are retracted with respect to the upper and lower chucks 81, 83.

When the orientation converting unit 63 converts the orientation of the substrates W from the vertical to the horizontal, the advancing/retracting unit 88 moves the two auxiliary chucks 85, 86 in such a manner that the substrates W housed in the vertical orientation in the V-shaped holding grooves 97 are brought into contact with the setting surfaces 95, respectively. A specific description will now be given with reference to FIG. 7(a) and 7(b). In FIG. 7(a) and 7(b), for the convenience of illustration, the upper and lower chucks 81, 83 are positioned at the left end of the substrates W, and auxiliary chucks 85, 86 are positioned at the right end of the substrate W.

FIG. 7(a) illustrates the condition immediately after the orientation converting unit 63 has received the substrates W from the second transporting mechanism WTR2, using the upper and lower chucks 81, 83 and the auxiliary chucks 85, 86. That is, each of the substrate W has its outer edge positioned at the rear end of the corresponding V-shaped holding groove 97, and in the middle of the width WD between the horizontal setting guide grooves 93, 94.

The advancing/retracting unit 88 can move the auxiliary chucks 85, 86 between a contact position and a standby position. When the orientations of the substrates W are to be converted, the advancing/retracting unit 88 retracts the auxiliary chucks 85, 86 from the standby position to the contact position (moves rearwards X). As a result, as illustrated in FIG. 7(b), the rear surfaces of the substrates W held in the vertical orientation by the respective V-shaped holding grooves 97 are brought into contact with or nearer to the respective setting surfaces 95 of the horizontal setting guide grooves 93, 94, provided to the upper and lower chucks 81, 83.

When the substrates W are not held by the auxiliary chucks 85, 86, the substrates W can move freely inside the horizontal setting guide grooves 93, 94. However, when the orientation is to be converted, the substrates W move and collide inside the horizontal setting guide groove 93, 94. As a result, particles may be formed. Therefore, by causing the advancing/retracting unit 88 to bring the substrates W into contact with the respective setting surfaces 95, for example, it is possible to alleviate the impact of the collision of the substrates W. Therefore, formation of particles can be suppressed.

The upper and lower chuck rotating unit 89 illustrated in FIG. 4(b) rotates the upper and lower chucks 81, 83 about a horizontal axis AX9 orthogonal to the direction (front-back direction X) in which the twenty-five substrates W in the vertical orientation held by the upper and lower chucks 81, 83 are aligned. As a result, the orientation of the twenty-five substrates W received from the two chucks 69, 70 are converted from the vertical to the horizontal. The horizontal axis AX9 extends in the width direction Y.

The upper and lower chuck rotating unit 89 is provided to the base frame 91. The base frame 91 includes, for example, a beam member 91A extending horizontally in the front-back direction X and two pillar members 91B supporting both ends of the beam member. The upper and lower chuck rotating unit 89 rotatably supports the upper and lower chucks 81, 83 about the horizontal axis AX9 via the support arm 90 having an L shape. The upper and lower chuck rotating unit 89 includes an electric motor, for example.

### 7. Description of Operation

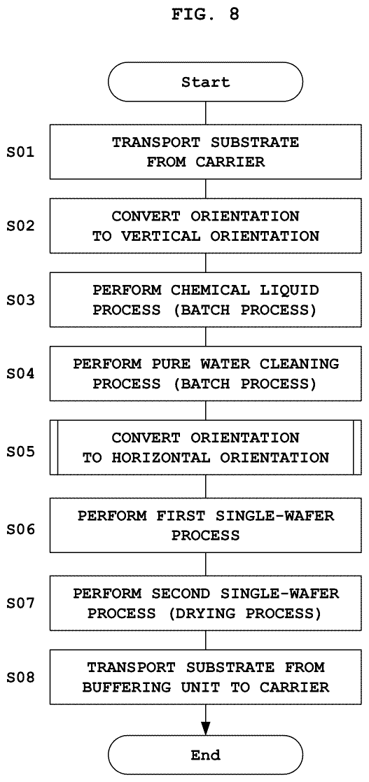

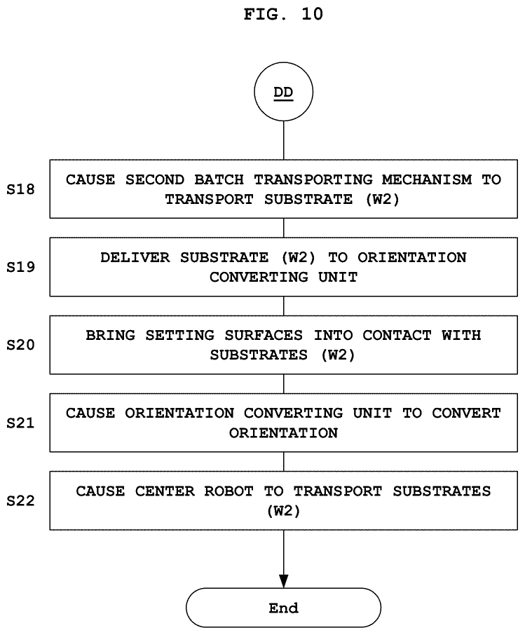

An operation of the substrate processing apparatus 1 will now be described with reference to the flowchart illustrated in FIGS. 8 to 10.

FIG. 1 will now be referred to. An external transporting robot, not illustrated, transports two carriers C onto the loading ports 9 one after another.

### [Step S01] Transport Substrates From Carrier

The carrier transporting mechanism 11 in the stocker block 3 transports a first carrier C from the loading port 9 onto the shelf 13A. The bulk transporting mechanism HTR of the transfer block 5 takes out twenty-five substrates W1 in the horizontal orientation from the first carrier C having been placed on the shelf 13A, and transports the twenty-five horizontally oriented substrates W1 to the orientation converting unit 23. The carrier transporting mechanism 11 then transports the empty first carrier C to the shelf 13B. The carrier transporting mechanism 11 then transports the second carrier C from the loading port 9 onto the shelf 13A. The bulk transporting mechanism HTR takes out the twenty-five horizontally oriented substrates W2 from the second carrier C having been placed on the shelf 13A, and transports the twenty-five substrates W2 to the orientation converting unit 23.

### [Step S02] Convert Orientation to Vertical Orientation

The fifty substrates W (W1, W2) corresponding to the two carriers C are transported to the orientation converting unit 23. As illustrated in FIG. 3(a) to 3(f), the orientation converting unit 23 and the pusher mechanism 25 align the fifty substrates W face-to-face at a half pitch (5 mm), and convert the orientation of the fifty substrates W from the horizontal orientation to the vertical orientation. The pusher mechanism 25 transports the fifty vertically oriented substrates W to the substrate delivery position PP established in the transfer block 5.

### [Step S03] Perform Chemical Liquid Process (Batch Process)

The first transporting mechanism WTR1 receives the fifty vertically oriented substrates W from the pusher mechanism 25 at the substrate delivery position PP, and transports the fifty substrates W to any one of the four lifters LF1 to LF4 corresponding to the four respective chemical liquid processing baths BT1 to BT4.

For example, the first transporting mechanism WTR1 transports the fifty substrates W onto the lifter LF1 of the chemical liquid processing bath BT1. The lifter LF1 receives the fifty substrates W at a position above the chemical liquid processing bath BT1. The lifter LF1 then immerses the fifty substrates W into phosphoric acid that is a chemical liquid in the chemical liquid processing bath BT1. With this, the fifty substrates W is subjected to the etching process. After the etching process, the lifter LF1 raises the fifty substrates W from the phosphoric acid in the chemical liquid processing bath BT1. Note that, when the fifty substrates are transported to the lifter LF2 to LF4 of another one of the chemical liquid processing bath BT2 to BT4, too, the processing that is the same as that in the chemical liquid processing bath BT1 is performed.

### [Step S04] Perform Pure Water Cleaning Process (Batch Process)

The first transporting mechanism WTR1 receives the fifty vertically oriented substrates W from the lifter LF1 (or the lifter LF2), for example, and transports the fifty substrates W onto the lifter LF5 of the water cleaning processing bath BT5. The lifter LF5 receives the fifty substrates W at a position above the water cleaning processing bath BT5. The lifter LF5 then immerses the fifty substrates W in the pure water in the water cleaning processing bath BT5. In the manner described above, the cleaning process is performed on the fifty substrates W.

When the first transporting mechanism WTR1 receives the fifty vertically oriented substrates W from one of the lifters LF3, LF4, the first transporting mechanism WTR1 transports the fifty substrates W to the lifter LF6 of the water cleaning processing bath BT6. The lifter LF6 receives the fifty substrates W at a position above the water cleaning processing bath BT6. The lifter LF6 then immerses the fifty substrates W in the pure water in the water cleaning processing bath BT6.

In the present embodiment, the second orientation converting mechanism 31 is provided on the opposite side of the transfer block 5 with the six batch processing baths BT1 to BT6 interposed therebetween. The first transporting mechanism WTR1 transports the fifty substrates W from, for example, the batch processing bath BT1 (BT3) on the side nearer to the transfer block 5, via the batch processing bath BT5 (BT6) on the side far from the transfer block 5, and to the second orientation converting mechanism 31, as a batch.

### [Step S05] Convert Orientation to Horizontal Orientation

The second orientation converting mechanism 31 converts the substrates W having been subjected to the cleaning process, from the vertical orientation to the horizontal orientation, as a batch. At this time, there are the following problems. That is, when the orientation of the fifty substrates W arranged at a half pitch (5 mm interval) is converted as a batch, one of the hand 35 of the center robot CR may fail to go into the gap between two adjacent substrates W of the fifty substrates W appropriately.

In addition, when the substrates W aligned face-to-face are converted to the horizontal orientation, some of the substrates W have the device surfaces facing upwards, and the other substrates W have their device surfaces facing downwards. It is not preferable, for example, for the hand 35 of the center robot CR to come into contact with the device surface of a substrate W. It is also not preferable for the substrates W with their device surfaces facing different sides to be transported into the single-wafer processing chambers SW1 to SW4.

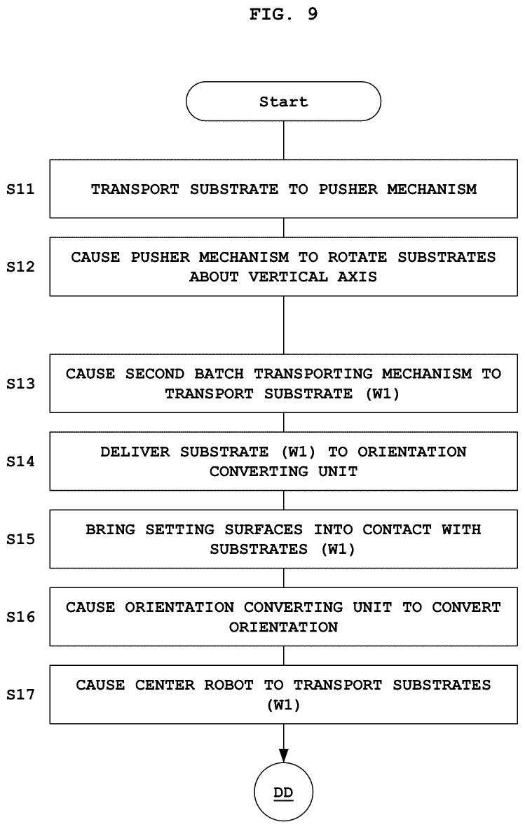

Therefore, in the present embodiment, the distance between the two adjacent substrates W is widened, and the device surface of each of the fifty substrates W is matched with those of the others. A specific description will be given with reference to the flowcharts of FIGS. 9 and 10, FIG. 11(a) to 11(d), FIG. 12(a) to 12(d), and FIG. 13(a) to 13(d).

### [Step S11] Transport Substrates to Pusher Mechanism

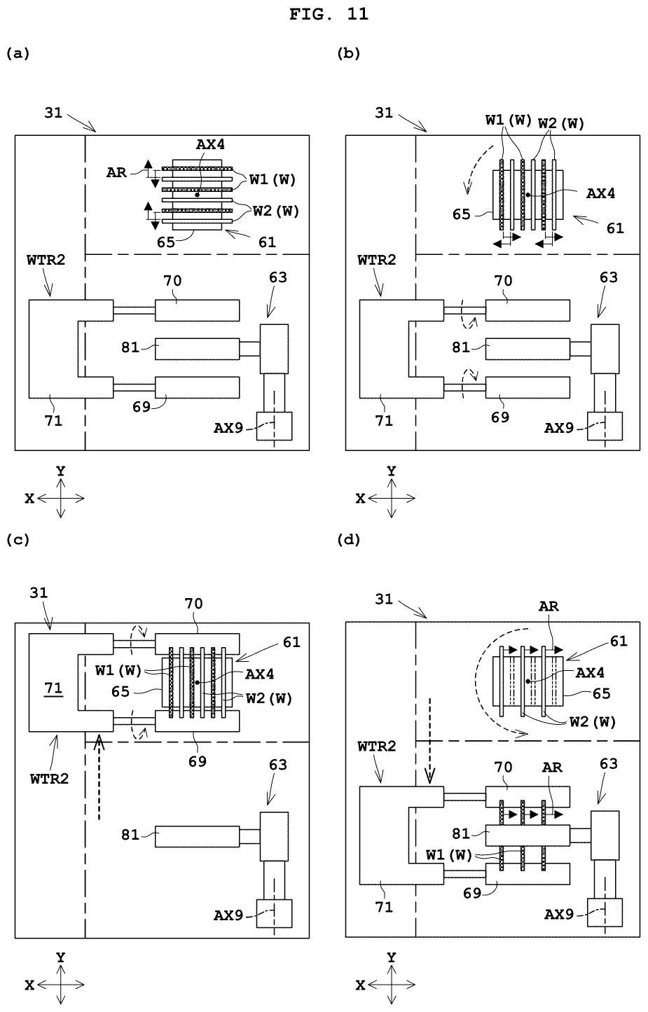

FIG. 11(a) will now be referred to. Note that FIG. 11(a) to 11(d) are plan views for explaining the operation of the second orientation converting mechanism 31. The first transporting mechanism WTR1 transports fifty substrates W from one of the lifters LF5 and LF6 to the pusher mechanism 61 of the second orientation converting mechanism 31 (see FIG. 1). The pusher 65 of the pusher mechanism 61 holds the fifty vertically oriented substrates W that are arranged face-to-face at a half pitch. The fifty substrates W are aligned in the width direction Y.

Note that the second transporting mechanism WTR2 waits on the side of the orientation converting unit 63 so as not to interfere with the first transporting mechanism WTR1. After the substrates W are transported to the pusher mechanism 61, the first transporting mechanism WTR1 moves from above the pusher mechanism 61.

### [Step S12] Cause Pusher Mechanism to Rotate Substrates About Vertical Axis

FIG. 11(b) will now be referred to. The rotating lift 67 of the pusher mechanism 61 rotates the fifty substrates W in a counterclockwise direction by 90 degrees about the vertical axis AX4 in plan view. As a result, the pusher mechanism 61 can deliver the substrate W to the second transporting mechanism WTR2, and can turn the device surfaces of the respective twenty-five substrates W1 of the first substrate group upwards when the orientation is converted.

### [step S13] Cause Second Batch Transporting Mechanism to Transport Substrates (W1)

The second transporting mechanism WTR2 is moved to the substrate standby side. That is, the second transporting mechanism WTR2 moves to bring the chucks 69, 70 above the fifty substrates W held by the pusher 65. The opening/closing unit 71 opens the chucks 69, 70 so that fifty substrates W can be passed between the chucks 69, 70.

FIG. 11(c) now be referred to. After the chucks 69, 70 reach above the substrates W, the lifting unit 73 of the second transporting mechanism WTR2 lowers the chucks 69, 70 to a level lower than the center of the substrates W. The opening/closing unit 71 then nips the fifty substrates W by closing the chucks 69, 70. At this time, the twenty-five substrates W1 are positioned in the twenty-five V-shaped holding grooves 78, respectively, and the twenty-five substrates W2 are positioned in the twenty-five passing grooves 80, respectively.

After the fifty substrates W are held between the chucks 69, 70, the lifting unit 73 lifts the chucks 69, 70. As a result, the second transporting mechanism WTR2 can extract the twenty-five substrates W1 arranged at a full pitch (for example, at an interval of 10 mm) from the fifty substrates W (W1, W2) held by the pusher 65. That is, the twenty-five substrates W2 of the second substrate group are left on the pusher 65.

FIG. 11(d) will now be referred to. The second transporting mechanism WTR2 transports the twenty-five substrates W1 into the space between the upper and lower chucks 81, 83 of the orientation converting unit 63, as a batch. At this time, the upper chuck 81 has been moved by the upper chuck moving unit 84 to an open position separated from the lower chuck 83. The auxiliary chucks 85, 86 are closed so as to be able to hold the substrates W that are in the vertical orientation. The auxiliary chucks 85, 86 may be open.

The rotating lift 67 in the pusher mechanism 61 then rotates the twenty-five substrates W2 held by the pusher 65 by 180 degrees about the vertical axis AX4. In this manner, it is possible to turn the device surfaces of the respective twenty-five substrates W2 of the second substrate group upwards when the orientation is converted. Furthermore, by rotating 180 degrees, the positions of the substrates W2 are shifted rearwards X by a half pitch, as compared with those before being rotated. Therefore, when the twenty-five substrates W2 are transported, the substrates W2 can be housed in the respective V-shaped holding grooves 78 of the chucks 69, 70. Note that this rotation of the substrate W2 by 180 degrees is preferably performed in steps S13 to S17.

### [Step S14] Deliver Substrates (W1) to Orientation Converting Unit

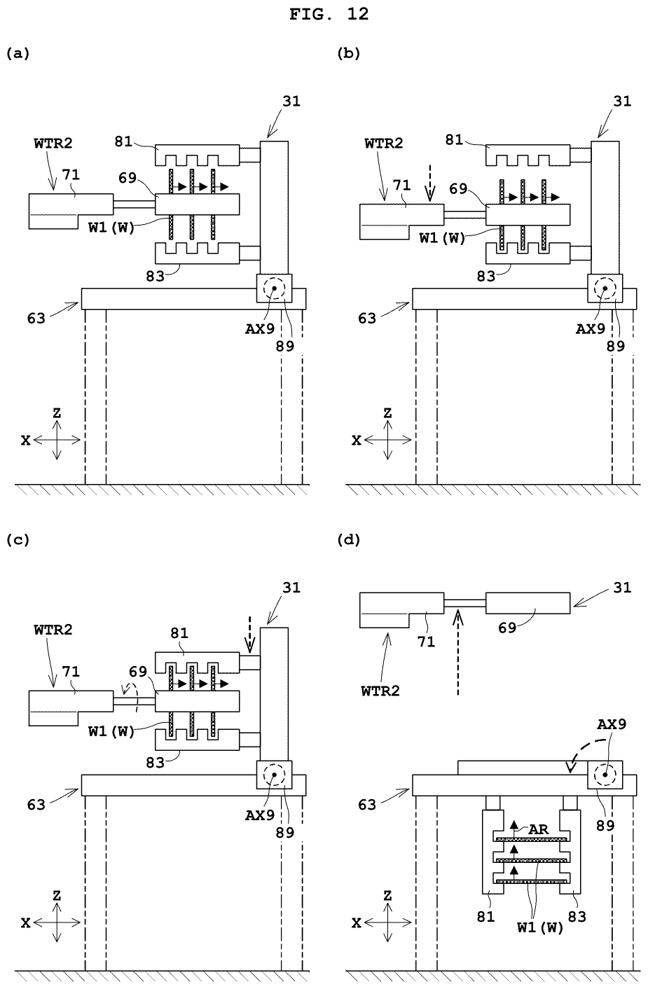

FIG. 12(a) will now be referred to. FIG. 12(a) to 12(d) are front views for explaining the operation of the second orientation converting mechanism 31, that is, schematics in a view from the single-wafer transporting area R2. Furthermore, FIG. 12(a) is a front view illustrating the twenty-five substrates W1 having been transported by the second transporting mechanism WTR2 illustrated in FIG. 11(d) into the space between the upper and lower chucks 81, 83.

FIG. 12(b) will now be referred to. The auxiliary chucks 85, 86 are closed so as to be able to hold the substrates W that are in the vertical orientation. The lifting unit 73 of the second transporting mechanism WTR2 lowers the twenty-five substrates W1 held by the chucks 69, 70 until the substrates W1 come into contact with the V-shaped holding grooves 97 of the auxiliary chucks 85, 86. That is, the lifting unit 73 lowers the twenty-five substrates W1 until the twenty-five substrates W1 are held in the twenty-five V-shaped holding grooves 97. When the twenty-five substrates W1 are held in the twenty-five V-shaped holding grooves 97 of each of the auxiliary chucks 85, 86, the outer edges of the twenty-five substrates W1 are housed in the second horizontal setting guide grooves 94 of the lower chuck 83, respectively.

The upper chuck moving unit 84 then lowers the upper chuck 81 in order to move the upper chuck 81 nearer to the lower chuck 83. As a result, the outer edges of the twenty-five substrates W1 are housed in the first horizontal setting guide grooves 93 of the upper chuck 81, respectively. Furthermore, the twenty-five substrates W1 are held (gripped) by the upper and lower chucks 81, 83 and the auxiliary chucks 85, 86.

FIG. 12(c) will now be referred to. The opening/closing unit 71 of the second transporting mechanism WTR2 then opens the chucks 69, 70. Accordingly, the twenty-five substrates W1 having been held are released. Furthermore, the twenty-five substrates W1 are then delivered to the orientation converting unit 63. The lifting unit 73 of the second transporting mechanism WTR2 then raises the chucks 69, 70 above the substrates W. As a result, the second transporting mechanism WTR2 is moved to a position where the orientation converting unit 63 is not interfered thereby.

### [Step S15] Bring Setting Surfaces Into Contact With Substrates (W1)

As illustrated in FIG. 6(b), the advancing/retracting unit 88 retracts the auxiliary chucks 85, 86 (moves the auxiliary chucks 85, 86 rearwards X). That is, the advancing/retracting unit 88 brings the twenty-five substrates W1 respectively held by the twenty-five V-shaped holding grooves 97 into contact with the setting surfaces 95 of the horizontal setting guide grooves 93, 94, respectively (see FIG. 7(a) and 7(b)). As a result, it is possible to suppress collision resultant of a movement of each of the substrates W1 while the orientation is converted, and during the operation of opening the auxiliary chucks 85, 86.

### [Step S16] Cause Orientation Converting Unit to Convert Orientation

FIG. 12(d) will now be referred to. The upper and lower chuck rotating unit 89 in the orientation converting unit 63 then rotates the upper and lower chucks 81,83 and the like holding the twenty-five substrates W1 by 90 degrees in the counterclockwise direction about the horizontal axis AX9. As a result, the orientations of the twenty-five substrates W1 of the first substrate group can be converted from the vertical to the horizontal.

After the rotation by 90 degrees, the auxiliary chuck opening/closing unit 87 opens the auxiliary chucks 85, 86 to a position where the transportation of the substrates W1 by the center robot CR is not obstructed thereby. That is, the auxiliary chucks 85, 86 are moved to the position indicated by the broken line in FIG. 5.

### [Step S17] Cause Center Robot to Transport Substrates (W1)

After the auxiliary chucks 85, 86 are opened, the center robot CR sequentially takes out the twenty-five substrates W1 held in the horizontal orientation by the upper and lower chucks 81, 83, and transports the substrates W1 to one of the single-wafer processing chambers SW1 and SW2, using the two hands 35. The interval between the substrates W has been widened from a half pitch to a full pitch. Therefore, the hands 35 of the center robot CR can go into the gap between the two adjacent substrates W favorably. In addition, the substrates W can be taken out favorably.

After the center robot CR transports the twenty-five substrates W1 of the first substrate group from the orientation converting unit 63, the center robot CR converts the orientation of the twenty-five substrates W2 of the second substrate group. Because steps S18 to S22 are similar to steps S13 to S17, redundant parts will be described briefly.

### [Step S18] Cause Second Batch Transporting Mechanism to Transport Substrates (W2)

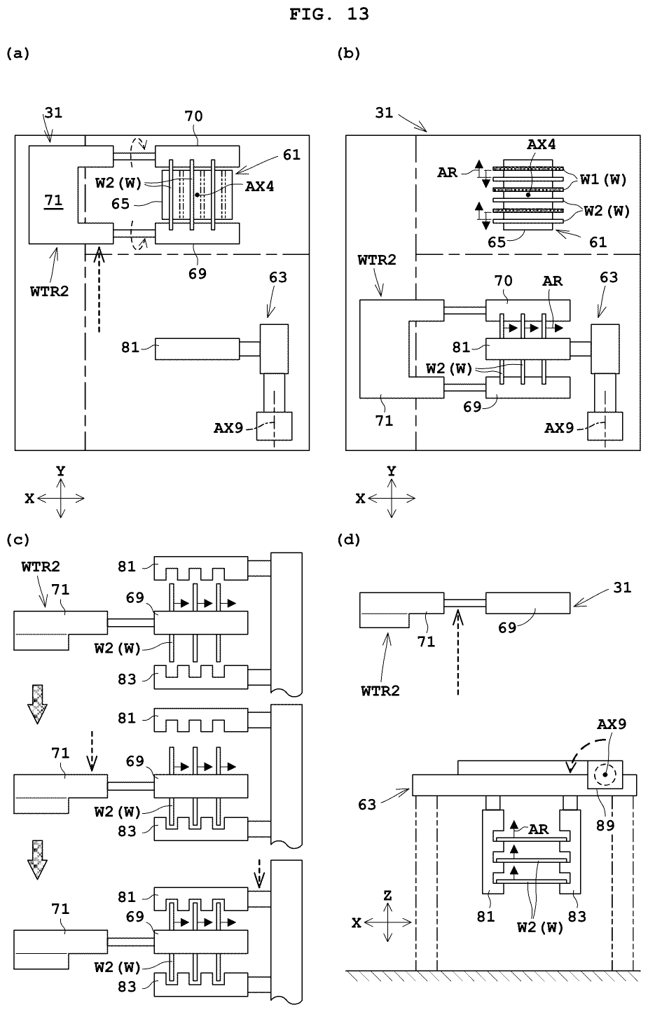

FIG. 13(a) will now be referred to. Note that FIG. 13(a) and 13(b) are plan views for explaining the operation of the second orientation converting mechanism 31. The second transporting mechanism WTR2 moves to bring the chucks 69, 70 above the twenty-five substrates W2 held by the pusher 65.

The lifting unit 73 of the second transporting mechanism WTR2 then lowers the chucks 69, 70 to a level lower than the center of the substrates W2. The opening/closing unit 71 then nips the twenty-five substrates W2 by closing the chucks 69, 70. In step S13, the substrates W2 have been rotated by 180 degrees, so that the positions of the substrate W2 have been shifted by a half pitch. Therefore, when the chucks 69, 70 are closed, the twenty-five substrates W2 are positioned in the twenty-five V-shaped holding grooves 78, respectively.

The lifting unit 73 then raises the chucks 69, 70. As a result, the second transporting mechanism WTR2 raises the twenty-five substrates W2 held by the pusher 65.

FIG. 13(b) will now be referred to. The second transporting mechanism WTR2 then transports the twenty-five substrates W2 into the space between the upper and lower chucks 81, 83 of the orientation converting unit 63, as a batch. After the second transporting mechanism WTR2 transports the twenty-five substrates W2, the pusher 65 does not hold the substrates W any longer. Therefore, the first transporting mechanism WTR1 can transport the next fifty substrates W from one of the lifters LF3, LF6 to the pusher 65.

### [Step S19] Deliver Substrates (W2) to Orientation Converting Unit

FIG. 13(c) will now be referred to. FIG. 13(c) and 13(d) are front views of the second orientation converting mechanism 31. The twenty-five substrates W2 held by the chucks 69, 70 are at a position between the upper and lower chucks 81, 83. The auxiliary chucks 85, 86 are also closed so as to be able to hold the substrates W2 that are in the vertical orientation. In addition, the auxiliary chucks 85, 86 have been moved from the contact position (the position in FIG. 7(b)) to the standby position (the position in FIG. 7(a)) by the advancing/retracting unit 88.

The lifting unit 73 of the second transporting mechanism WTR2 lowers the twenty-five substrates W2 held by the chucks 69, 70 until the twenty-five V-shaped holding grooves 97 of each of the auxiliary chucks 85, 86 hold the twenty-five substrates W2. The upper chuck moving unit 84 then lowers the upper chuck 81. As a result, the twenty-five substrates W2 are held (gripped) by the upper and lower chucks 81, 83 and the auxiliary chucks 85, 86.

The opening/closing unit 71 of the second transporting mechanism WTR2 then opens the chucks 69, 70. As a result, the twenty-five substrates W2 having been held are released, and the twenty-five substrates W2 are delivered to the orientation converting unit 63. The lifting unit 73 of the second transporting mechanism WTR2 then raises the chucks 69, 70 above the substrates W where the orientation converting unit 63 is not obstructed thereby.

### [Step S20] Bring Setting Surfaces Into Contact With Substrates (W2)

The advancing/retracting unit 88 then brings the twenty-five substrates W2 respectively held by the twenty-five V-shaped holding grooves 97 into contact with the setting surfaces 95 of the horizontal setting guide grooves 93, 94, respectively (see FIG. 7(a) and 7(b)).

### [Step S21] Cause Orientation Converting Unit to Convert Orientation

FIG. 13(d) will now be referred to. The upper and lower chuck rotating unit 89 in the orientation converting unit 63 rotates the upper and lower chucks 81,83 and the like holding the twenty-five substrates W2 by 90 degrees in the counterclockwise direction about the horizontal axis AX9. With this, the orientation of the twenty-five substrates W2 in the vertical direction is converted to the horizontal orientation. After rotating 90 degrees, the auxiliary chuck opening/closing unit 87 opens the auxiliary chucks 85, 86 to the positions indicated by the broken line in FIG. 5.

### [Step S22] Cause Center Robot to Transport Substrates (W2)

After the auxiliary chucks 85, 86 are opened, the center robot CR sequentially takes out the twenty-five substrates W2 that are in the horizontal orientation, and transports the substrates W2 to one of the first single-wafer processing chamber SW1 and the second single-wafer processing chamber SW2.

### [Step S06] Perform First Single-Wafer Process

The description goes back the flowchart of FIG. 8. The center robot CR transports the substrates W (W1, W2) from the orientation converting unit 63 to the first single-wafer processing chamber SW1, for example. In the first single-wafer processing chamber SW1, the rotating processing unit 45 rotates the substrate W, by holding the substrate W in such a manner that the device surface thereof facing upwards, and the pure water is supplied onto the device surface, via the nozzle 47. Thereafter, in the first single-wafer processing chamber SW1, IPA is supplied from the nozzle 47 onto the device surface (upper surface) of the substrate W, thereby replacing the pure water on the substrate W with the IPA.

### [Step S07] Perform Second Single-Wafer Process (Drying Process)

The center robot CR then takes out the substrate W wetted with IPA from the first single-wafer processing chamber SW1 (SW2), and transports the substrate W to one of the single-wafer processing chambers SW3, SW4. Each of the single-wafer processing chambers SW3, SW4 performs the process of drying the substrate W, using carbon dioxide in the supercritical state (supercritical fluid). With the drying process using the supercritical fluid, collapses of the pattern on the pattern surface of the substrate W is suppressed.

### [Step S08] Transport Substrate From Buffering Unit to Carrier

The center robot CR transports the substrate W having been subjected to the drying process from one of the single-wafer processing chambers SW3, SW4 to any one of the placing shelves in the buffering unit 33. When the substrates W1 corresponding to one lot (twenty-five) have been transported to the buffering unit 33, the bulk transporting mechanism HTR transports the twenty-five substrates W1 as a batch, from the buffering unit 33 into the empty first carrier C having been placed on the shelf 13A. The carrier transporting mechanism 11 in the stocker block 3 then transports the first carrier C to the loading port 9.

When the substrates W2 corresponding to one lot have been placed to the buffering unit 33, the bulk transporting mechanism HTR transports the twenty-five substrates W2 as a batch, from the buffering unit 33 into the empty second carrier C having been placed on the shelf 13A. The carrier transporting mechanism 11 in the stocker block 3 then transports the second carrier C to the loading port 9. An external transporting mechanism, not illustrated, transports two carriers C to the next destination one after another.

According to the present embodiment, the batch processing area R1, the single-wafer processing area R3, and the single-wafer transporting area R2 are provided in a manner extending from the side of the transfer block 5. The six batch processing baths BT1 to BT6 are arranged in the front-back direction X in which the batch processing area R1 extends.

Furthermore, the four single-wafer processing chambers SW1 to SW4 are arranged in the front-back direction X in which the single-wafer processing area R3 extends. In addition, the center robot CR is provided in the single-wafer transporting area R2 that is disposed between the six batch processing baths BT1 to BT6 and the four single-wafer processing chambers SW1 to SW4. The first transporting mechanism WTR1 is provided in the batch substrate transporting area R4, along the six batch processing baths BT1 to BT6. Therefore, the substrate processing apparatus 1 according to the present embodiment can transport substrates W smoothly.

This operation will now be explained specifically. The bulk transporting mechanism HTR of the transfer block 5 can take out a plurality of substrates W from the carrier C as a batch, and transport the plurality of substrates W to the first orientation converting mechanism 15 as a batch. The first transporting mechanism WTR1 transports a plurality of substrates W to and from the substrate delivery position PP, the batch processing baths BT1 to BT6, and the second orientation converting mechanism 31. Furthermore, the center robot CR transports the substrates W to and from the second orientation converting mechanism 31, the four single-wafer processing chambers SW1 to SW4, and the buffering unit 33. The bulk transporting mechanism HTR receives a plurality of substrates W from the buffering unit 33 as a batch, and stores the plurality of substrates W into the carrier C as a batch.

Therefore, it is possible to transport the plurality of substrates W directly from the transfer block 5 to the batch processing area R1, without transporting to the single-wafer processing area R3 before transporting to the batch processing area R1. In addition, the bulk transporting mechanism HTR transports a plurality of substrates W from and to the carrier C, the first orientation converting mechanism 15, and the buffering unit 33 as a batch, without accessing each of the single-wafer processing chambers SW1 to SW4. As a result, it is possible to transport a plurality of substrates W quickly from the carrier C to the first orientation converting mechanism 15, and to transport a plurality of substrates W quickly from the buffering unit 33 to the carrier C. Hence, the substrate processing apparatus 1 according to the present embodiment can transport substrates W smoothly. Therefore, the throughput can be improved. In addition, because the single-wafer processing chambers SW1 to SW4 are provided along the direction in which the single-wafer transporting area R2 extends, a larger number of single-wafer processing chambers can be provided.

Furthermore, the second orientation converting mechanism 31 is provided on the opposite side of the transfer block 5 with the six batch processing baths BT1 to BT6 interposed therebetween. For example, the center robot CR transports the plurality of substrates W from the batch processing bath BT1 (BT4) on the side nearer to the transfer block 5, via the batch processing bath BT5 (BT6) on the side farther away from the transfer block 5, and to the second orientation converting mechanism 31.

The plurality of substrates W can be transported from the transfer block 5 to the second orientation converting mechanism 31 while performing a batch process in the batch processing baths BT1 to BT6, and then the plurality of substrates W can be transported from the second orientation converting mechanism 31 to the transfer block 5 while performing a single-wafer process in the single-wafer processing chamber SW1 to SW4. In this manner, a plurality of substrates W can be transported in a manner delineating a circle within the processing block 7, so that the substrates W can be transported smoothly.

Furthermore, the second orientation converting mechanism 31 includes the pusher 65 holds the plurality of substrates W in the vertical orientation transported by the first transporting mechanism WTR1; the second transporting mechanism WTR2 capable of extracting two or more substrates W from the plurality of substrates W held by the pusher 65; and the orientation converting unit 63 that converts an orientation of the two or more substrates W extracted by the second transporting mechanism WTR2 from the vertical orientation to the horizontal orientation, as a batch. With this, the orientation converting unit 63 can convert the orientation of the two or more substrates W extracted by the second transporting mechanism WTR2.

### SECOND EMBODIMENT

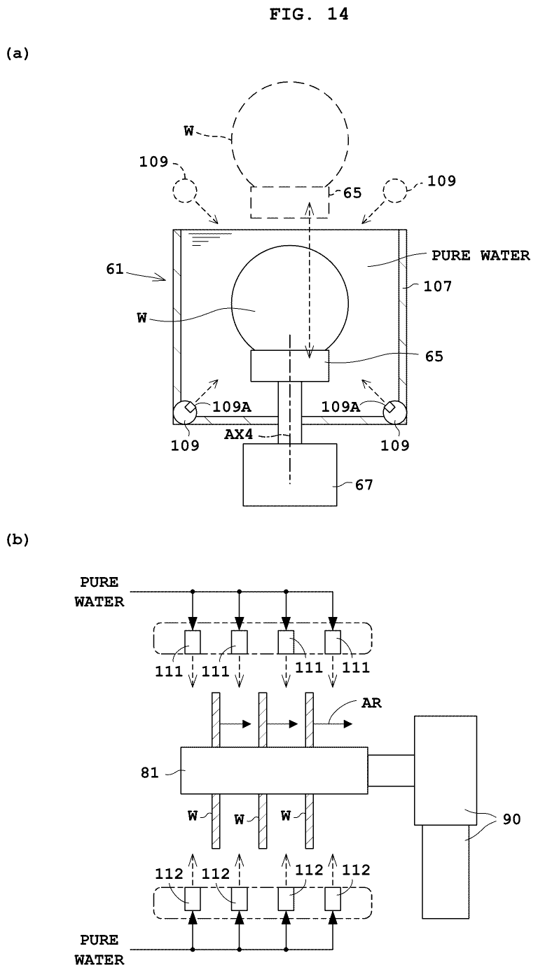

A second embodiment according to the present invention will now be described with reference to drawings. Note that redundant descriptions with those in the first embodiment will be omitted. FIG. 14(a) is a longitudinal sectional view illustrating the pusher mechanism 61 of the second orientation converting mechanism 31 according to the second embodiment. FIG. 14(b) is a plan view illustrating the second orientation converting mechanism 31 according to the second embodiment.

FIG. 14(a) will now be referred to. The pusher mechanism 61 of the second orientation converting mechanism 31 according to the second embodiment includes a standby bath 107 storing therein a liquid for immersing the substrates W held by the pusher 65 as the pusher 65 is lowered, and two ejection pipes 109 for supplying pure water (DIW), for example, as the liquid to the standby bath 107. The ejection pipes 109 extend linearly in the front-back direction X or the width direction Y.

Each of the ejection pipes 109 includes a plurality of ejection ports 109A (nozzles for holders) in a direction in which the ejection pipe 109 extends. Each of the plurality of ejection ports 109A ejects pure water. The standby bath 107 stores therein the pure water ejected from the ejection pipe 109.

For example, while the orientation converting unit 63 is converting the orientation of the substrates W1, for example, as illustrated in FIG. 11(d), the substrates W2 kept standby is immersed in pure water in the standby bath 107. In this manner, the substrates W can be prevented from drying.

It is also possible for the standby bath 107 not to store pure water. In such a case, the ejection ports 109A on the ejection pipes 109 may supply pure water as shower or mist to the substrates W held by the pusher 65. The ejection ports 109A may also be disposed at a position higher than the substrates W as the ejection pipes 109 indicated by dashed lines in FIG. 14(a). When pure water is supplied to the substrate W as shower or mist, the standby bath 107 may be provided or not be provided.

FIG. 14(b) will now be referred to. The second orientation converting mechanism 31 includes a first group of nozzles 111 and a second group of nozzles 112. The nozzles 111, 112 are nozzles for the orientation converting unit 63. The nozzles 111, 112 supply, for example, pure water (DIW) as a liquid to the substrate W held by the upper and lower chucks 81, 83 of the orientation converting unit 63 as shower or mist. The first group of nozzles 111 and the second group of nozzles 112 are disposed in such a manner that the substrates W are positioned therebetween, in plan view. The nozzles 111, 112 are provided at positions higher than the substrates W. The nozzles 111, 112 may also be configured to be movable so as not to interfere with the second transporting mechanism WTR2.

The upper and lower chuck rotating unit 89 keeps the orientation of the substrates W held by the upper and lower chucks 81, 83 to one of a vertical orientation and an oblique orientation. In this state, the nozzles 111, 112 supply shower-like or mist-like pure water to the substrate W held by the upper and lower chucks 81, 83. Note that the oblique orientation is an orientation in which the device surface of the substrate faces upwards.

For example, when the center robot CR interrupts the transportation of the substrates W, the substrates W held by the upper and lower chucks 81, 83 can be prevented from drying. In addition, if the orientation of the substrates W is the horizontal orientation when the pure water is supplied as shower or mist, the pure water is less likely to reach the entire surface of the device surface. However, when the orientation of the substrates W is set to one of the vertical orientation and the upward oblique orientation of the device surface, pure water as shower or mist easily reaches the entire device surfaces.

Note that the substrate processing apparatus 1 may use both the configuration illustrated in FIG. 14(a) and the configuration illustrated in FIG. 14(b). In addition, the substrate processing apparatus 1 may also use only one of the configuration illustrated in FIG. 14(a) and the configuration illustrated in FIG. 14(b).

### THIRD EMBODIMENT

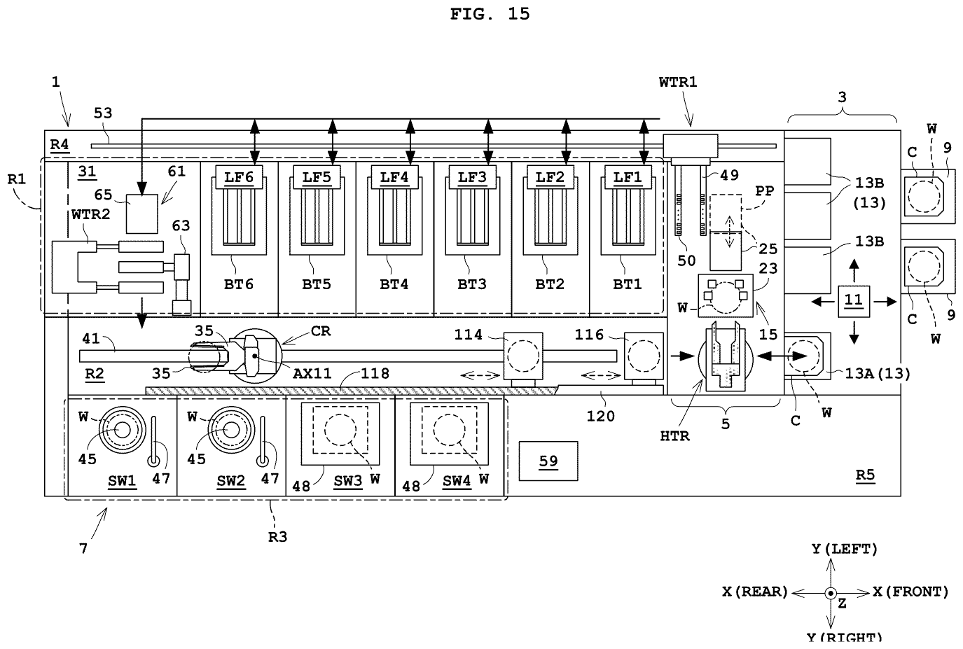

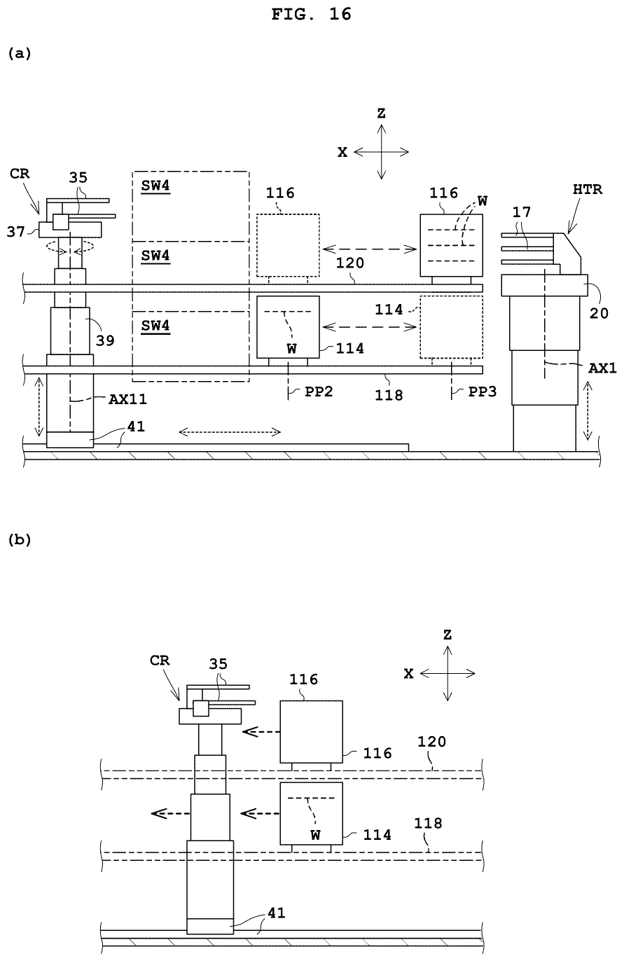

A third embodiment according to the present invention will now be described with reference to drawings. Note that redundant descriptions with those in the first and the second embodiments will be omitted. FIG. 15 is a plan view illustrating a schematic configuration of a substrate processing apparatus 1 according to the third embodiment. FIG. 16(a) and 16(b) are side views for explaining buffering units 114, 116 according to the third embodiment.

The buffering units 33 of the first and the second embodiment are fixed to the floor surface at the boundary between the transfer block 5 and the single-wafer transporting area R2, without moving. In this regard, the two buffering units 114, 116 according to the third embodiment are movable in the front-back direction X, in which the single-wafer transporting area R2 extends.

FIG. 15, and 16(a) will now be referred to. The substrate processing apparatus 1 includes a first buffering unit 114, a second buffering unit 116, a horizontally moving unit 118, and a horizontally moving unit 120. Each of the two buffering units 114, 116 includes a plurality of (e.g., twenty-five) placing shelves arranged at a predetermined interval (full pitch) along the vertical direction Z. Each of the horizontally moving units 118, 120 corresponds to a placing unit moving mechanism according to the present invention. In FIG. 15, the horizontally moving unit 120 is illustrated as being cut halfway, but the horizontally moving unit 120 is configured in the same manner as the horizontally moving unit 118.

The two buffering units 114, 116 are provided movably in the single-wafer transporting area R2. The horizontally moving unit 118 moves the first buffering unit 114 in the front-back direction X. The horizontally moving unit 120 moves the second buffering unit 116 in the front-back direction X. Each of the two horizontally moving units 118, 120 includes a linear actuator including an electric motor. Each of the horizontally moving units 118, 120 is provided in a manner not interfering with the center robot CR.

As illustrated in FIG. 16(a), each of the buffering units 114, 116 moves, for example, between the vicinity of the fourth single-wafer processing chamber SW4 and the boundary between the single-wafer transporting area R2 and the transfer block 5. This operation will now be explained specifically. Each of the buffering units 114, 116 is moved between a collecting position PP2 and a bulk returning position PP3.

The collecting position PP2 is a position adjacent to the fourth single-wafer processing chamber SW4, on the side of the transfer block 5 in a view in the width direction Y (see FIG. 16(a)). Alternatively, the collecting position PP2 is a position between the nearest fourth single-wafer processing chamber SW4 and the transfer block 5 in a view from the width direction Y, and is a position farther away from the transfer block 5 than the bulk returning position PP3. The bulk returning position PP3 is a position where the bulk transporting mechanism HTR can access, and is nearer to the transfer block 5 than the collecting position PP2. Both of the positions PP2 and PP3 are preset positions.

The substrate processing apparatus 1 according to the third embodiment operates as follows. The horizontally moving unit 118, for example, moves the first buffering unit 114 to the collecting position PP2.

The center robot CR transports the substrate W1 having been dried in any one of the single-wafer processing chambers SW3, SW4 to the first buffering unit 114. Because the center robot CR does not need to move near the batch transporting robot HTR, the efficiency of transportation of the substrate W can be improved.

When the twenty-five substrates W1 are transported to the first buffering unit 114, the horizontally moving unit 118 moves the first buffering unit 114 from the collecting position PP2 to the bulk returning position PP3. The bulk transporting mechanism HTR then transports the twenty-five substrates W1 from the first buffering unit 114 to the empty carrier C having been placed on the shelf 13A, as a batch. When the first buffering unit 114 becomes empty, the horizontally moving unit 118 moves the empty first buffering unit 114 from the bulk returning position PP3 to the collecting position PP2.

After the twenty-five substrates W1 are transported to the first buffering unit 114, the center robot CR transports the substrates W2 having been dried in any one of the single-wafer processing chambers SW3, SW4 to the second buffering unit 116 at the collecting position PP2.

Once the twenty-five substrates W2 are transported to the second buffering unit 116, the horizontally moving unit 120 moves the second buffering unit 116 from the collecting position PP2 to the bulk returning position PP3. The bulk transporting mechanism HTR then transports the twenty-five substrates W2 from the second buffering unit 116 to the empty carrier C having been placed on the shelf 13A, as a batch. When the second buffering unit 116 becomes empty, the horizontally moving unit 120 moves the second buffering unit 116 from the bulk returning position PP3 to the collecting position PP2. In this manner, the movement of the two buffering units 114, 116 is repeated.

A modification of the third embodiment will now be described. In the third embodiment, the two buffering units 114, 116 are moved between the preset collecting position PP2 (constant position) and the bulk returning position PP3. In this regard, each of the two buffering units 114, 116 may be moved in a manner following the center robot CR, without setting the collecting position PP2.

As illustrated in FIG. 16(b), the horizontally moving unit 118 moves the first buffering unit 114 in the front-back direction X in a manner following the center robot CR. The horizontally moving unit 120 also moves the second buffering unit 116 in the front-back direction X in a manner following the center robot CR. As a result, because each of the buffering units 114, 116 is moved in a manner following the center robot CR, the center robot CR can transport the substrates W quickly to each of the buffering units 114, 116.

For example, when a preset number of (e.g., twenty-five) substrates W1 (W2) are transported to the first buffering unit 114, the horizontally moving unit 118 moves the first buffering unit 114 to the bulk returning position PP3. The bulk transporting mechanism HTR is thus allowed to return twenty-five substrates W1 (W2) to the carrier C. Once the first buffering unit 114 is emptied by the bulk transporting mechanism HTR, the horizontally moving unit 118 moves the first buffering unit 114 again in the front-back direction X in a manner following the center robot CR.

Furthermore, according to the present embodiment, each of the buffering units 114, 116 is provided movably in the single-wafer transporting area R2. The horizontally moving units 118, 120 move the respective buffering units 114, 116 in a direction in which the single-wafer transporting area R2 extends. Because the buffering units 114, 116 are moved by the horizontally moving units 118, 120, respectively, the center robot CR does not need to move near the bulk transporting mechanism HTR, so that the efficiency of transportation of the substrates W can be improved.

Furthermore, the horizontally moving units 118, 120 move the respective buffering units 114, 116 in the front-back direction X, in which the single-wafer transporting area R2 extends, in a manner following the center robot CR. Because each of the buffering units 114, 116 is moved following the center robot CR, the center robot CR can quickly transport the substrates W to each of the buffering units 114, 116.

### FOURTH EMBODIMENT

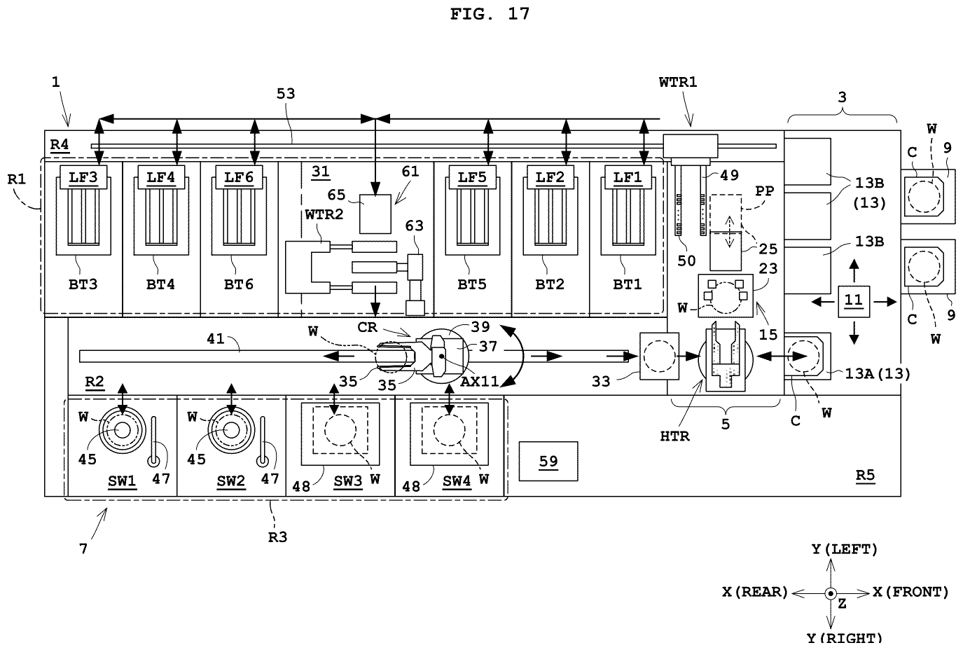

A fourth embodiment according to the present invention will now be described with reference to drawings. Note that redundant descriptions with those in the first to the third embodiments will be omitted. FIG. 17 is a plan view illustrating a schematic configuration of a substrate processing apparatus 1 according to the fourth embodiment.

In the first to the third embodiments, the second orientation converting mechanism 31 is provided on the opposite side of the transfer block 5 with the six batch processing baths BT1 to BT6 interposed therebetween. The position of the second orientation converting mechanism 31 is, however, not limited thereto. For example, in the fourth embodiment, the second orientation converting mechanism 31 may be provided between the two batch processing baths BT5, BT6, among the plurality of (e.g., six) batch processing baths BT1 to BT6. The two batch processing baths are not limited to the batch processing baths BT5, BT6.

FIG. 17 will now be referred to. The second orientation converting mechanism 31 is provided between the two batch processing baths BT5, BT6. That is, the second orientation converting mechanism 31 is disposed between the three batch processing baths BT1, BT2, and BT5 and the three batch processing baths BT3, BT4, and BT6. In addition, the water cleaning processing baths BT5, BT6 are disposed on both sides of the second orientation converting mechanism 31.

In FIG. 17, the first transporting mechanism WTR1 transports the plurality of substrates W from the batch processing bath BT1 on the side nearer to the transfer block 5 to the second orientation converting mechanism 31 as a batch, and transports the plurality of substrates W from the batch processing bath BT4 on the side far away from the transfer block 5 to the second orientation converting mechanism 31 as a batch. That is, a plurality of (for example, fifty) substrates W are transported to one of the two chemical liquid processing baths BT1, BT2 and to the water cleaning processing bath BT5, in the order listed herein, and are transported to one of the two chemical liquid processing baths BT3, BT4 and to the water cleaning processing bath BT6, in the order listed herein.

According to the present embodiment, because the second orientation converting mechanism 31 is provided between the two batch processing baths BT5, BT6, it is possible to ensure relatively uniform distances between the second orientation converting mechanism 31 and the single-wafer processing chambers SW1 to SW4. Therefore, the center robot CR can transport the substrates W around the center of the single-wafer transporting area R2 as a base point. Therefore, the distance by which the center robot CR is moved can be kept short, so that the efficiency of transporting the substrates W can be improved.

### FIFTH EMBODIMENT

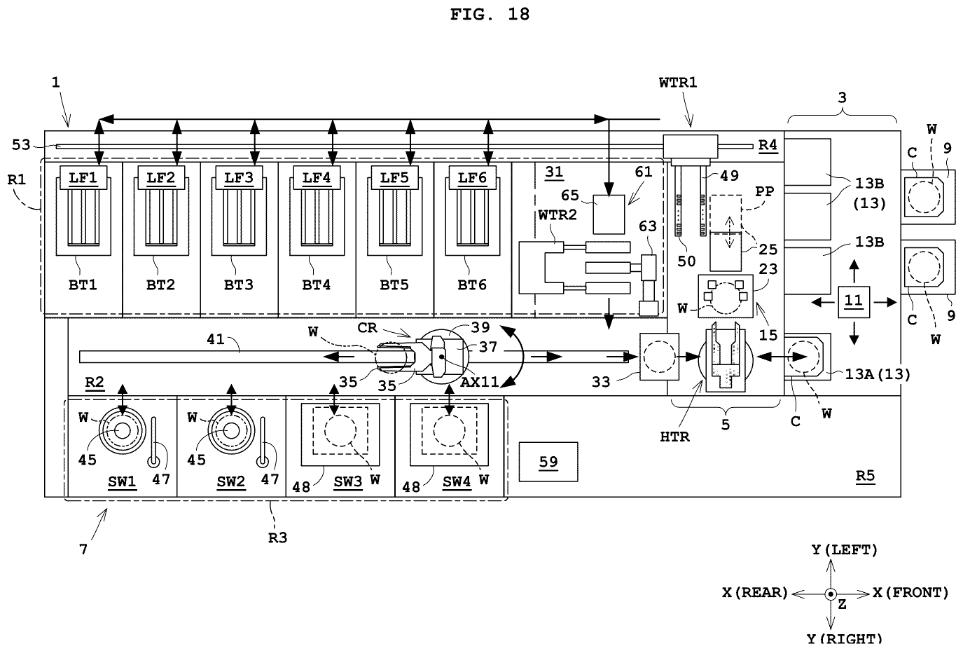

A fifth embodiment according to the present invention will now be described with reference to drawings. Note that redundant descriptions with those in the first to the fourth embodiments will be omitted. FIG. 18 is a plan view illustrating a schematic configuration of a substrate processing apparatus 1 according to the fifth embodiment.

In the first to the third embodiments, the second orientation converting mechanism 31 is provided on the opposite side of the transfer block 5 with the six batch processing baths BT1 to BT6 interposed therebetween. The position of the second orientation converting mechanism 31 is, however, not limited thereto. For example, in the fifth embodiment, the second orientation converting mechanism 31 is provided between the transfer block 5 and the plurality of (e.g., six) batch processing baths BT1 to BT6.

FIG. 18 will now be referred to. The second orientation converting mechanism 31 is positioned adjacently to the transfer block 5. The batch substrate transporting mechanism WTR1 transports the plurality of substrates W from the batch processing bath BT1 (BT3) on the side far from the transfer block 5, via the batch processing bath BT5 (BT6) on the side near the transfer block 5, and to the second orientation converting mechanism 31.

According to the present embodiment, the second orientation converting mechanism 31 is positioned near the transfer block 5. Therefore, the substrates W can be transported using the side of the transfer block 5 as the base point. In addition, because the chemical liquid processing baths BT1 to BT4 can be placed at positions away from the transfer block 5, it is possible to suppress an adverse effect of the chemical liquid atmosphere, e.g., corrosion of a mechanism such as the bulk transporting mechanism HTR in the transfer block 5. Furthermore, a large number of the single-wafer processing chambers SW1 to SW4 can be arranged along the single-wafer transporting area R2.

The present invention is not limited to the embodiments described above, and the following modifications are still possible.

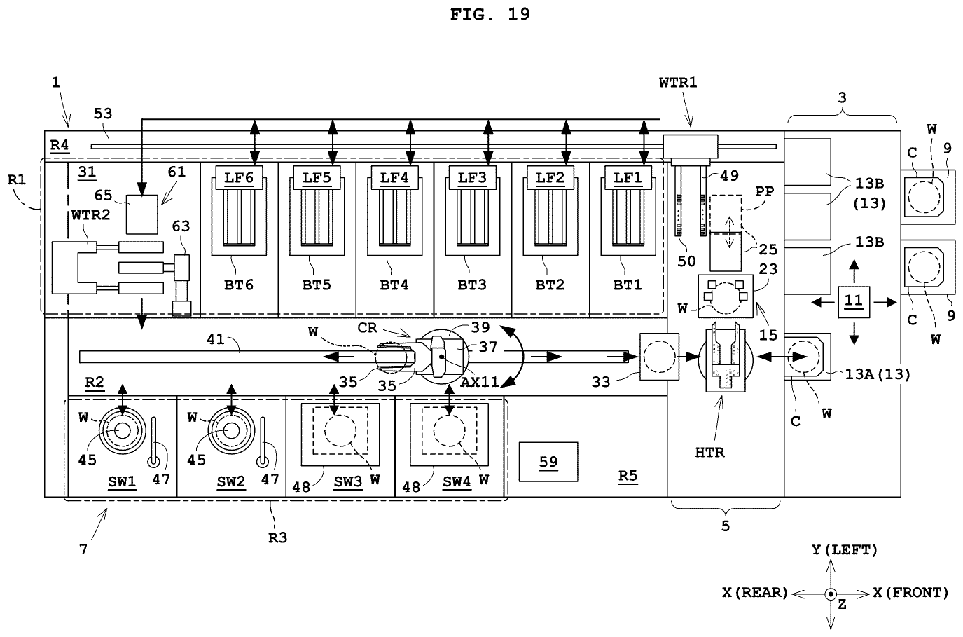

(1) In each of the embodiments described above, the electrical equipment area R5 of the substrate processing apparatus 1 in FIG. 1 is positioned adjacently to the stocker block 3. In this regard, the electrical equipment area R5 of the substrate processing apparatus 1 of FIG. 19 may not be positioned adjacently to the stocker block 3. That is, one end of the electrical equipment area R5 in FIG. 19 may be positioned adjacently to the transfer block 5, and extend up to the single-wafer processing area R3 in the front-back direction X.

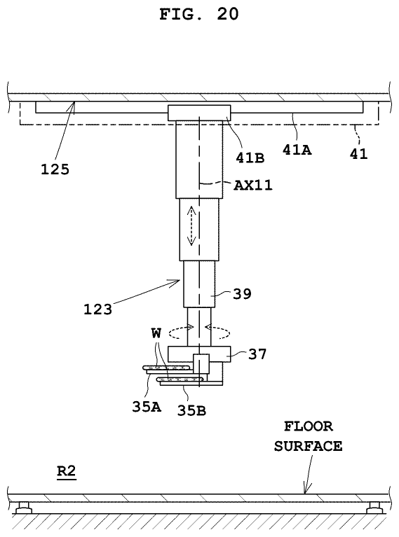

(2) In each of the embodiments and the modification described above, the guide rail of the horizontally moving unit 41 of the center robot CR is provided on the floor surface of the single-wafer transporting area R2. Alternatively, a guide rail 41A of the horizontally moving unit 41 in the center robot CR may be provided above the single-wafer transporting area R2, and the rotating lift 39 and the like of the center robot CR may be suspended upside down from the guide rail 41A, as illustrated in FIG. 20.

The center robot CR includes a mechanism main unit 123 (two hands 35A, 35B, advancing/retracting unit 37, and the rotating lift 39) and a horizontally moving unit 41. The horizontally moving unit 41 includes, for example, the guide rail 41A, a slider 41B, a screw shaft, and an electric motor. The guide rail 41A is provided above the single-wafer transporting area R2 and along the single-wafer transporting area R2 in the front-back direction X. For example, the guide rail 41A is provided on a ceiling surface 125 of the single-wafer transporting area R2 (or the processing block 7). The guide rail 41A corresponds to an upper rail according to the present invention.

The mechanism main unit 123 is suspended from the guide rail 41A, and moves in the front-back direction X along the guide rail 41A.

As a result, the advancing/retracting unit 37 and the rotating lift 39 are prevented from being contaminated with droplets dripping from a wet substrate W. When the advancing/retracting unit 37 and the like are contaminated with droplets, the center robot CR may fail, but such a failure can be avoided.

As illustrated in FIG. 20, when the first hand 35A is provided above the second hand 35B, the first hand 35A is used in transporting the substrate W subjected to the drying processing, and the second hand 35B is used in transporting the wet substrates W from the second orientation converting mechanism 31 to one of the single-wafer processing chambers SW3, SW4.

(3) In each of the embodiments and the modification described above, the single-wafer processing chambers SW3, SW4 perform the process of drying the substrate W using the supercritical fluid. In this regard, the single-wafer processing chambers SW3, SW4 may include a rotating processing unit 45 and a nozzle 47, similarly to the single-wafer processing chambers SW1, SW2. In such a case, each of the single-wafer processing chambers SW1 to SW4 supplies, for example, pure water and IPA to the substrate W in the order listed herein, and then performs a process of drying (spin-drying) the substrate W.

(4) In each of the embodiments and the modification described above, the configuration illustrated in FIG. 4(a) is used as the second orientation converting mechanism 31. In this respect, for example, a configuration similar to that of the first orientation converting mechanism 15 illustrated in FIG. 3(a) to 3(f) may be used as the second orientation converting mechanism 31.

(5) In each of the embodiments and the modifications described above, each of the batch processing baths BT1 to BT6 handles the fifty substrates W arranged face-to-face at a half pitch. However, each of the batch processing baths BT1 to BT6 may process the substrates W arranged in face-to-back so that the device surfaces of all the substrates W face the same direction. Each of the batch processing baths BT1 to BT6 may process the twenty-five substrates W corresponding one carrier C, and arranged at a full pitch. When the fifty substrates W are arranged face-to-back in FIG. 11(b), twenty-five substrates W1 or twenty-five substrates W2 are extracted by causing the opening/closing unit 71 to move the two chucks 69, 70 in the front-back direction X in which the substrates W are aligned.

### REFERENCE SIGNS LIST

1 substrate processing apparatus
3 stocker block
5 transfer block
7 processing block
13A shelf
HTR bulk transporting mechanism
15 first orientation converting mechanism
PP substrate delivery position
R1 batch processing area
R2 single-wafer transporting area
R3 single-wafer processing area
R4 batch substrate transporting area
31 second orientation converting mechanism
BT1 to BT6 batch processing bath
SW1 to SW4 single-wafer processing chamber
CR center robot
33 buffering unit
41 horizontally moving unit
41A guide rail
WTR1 first transporting mechanism
59 control unit
61 pusher mechanism
WTR2 second transporting mechanism
63 orientation converting unit
114, 116 buffering unit
118, 120 horizontally moving unit
123 mechanism main unit
125 ceiling surface

1. A substrate processing apparatus configured to perform a batch process in which a plurality of substrates are processed as a batch, and a single-wafer process in which one substrate is processed at a time, continuously, the substrate processing apparatus comprising:
a stocker block;
a transfer block that is positioned adjacently to the stocker block;
a processing block that is positioned adjacently to the transfer block; and
a substrate placing unit where a plurality of substrates in a horizontal orientation are placed along a vertical direction at a predetermined interval between the plurality of substrates, wherein
the stocker block that accommodates at least one carrier storing a plurality of substrates in the horizontal orientation at the predetermined interval between the plurality of substrates in a vertical direction, and includes at least one carrier placing shelf for taking out and storing a substrate, the carrier placing shelf on which the carrier is placed so as to enable a substrate to be taken out from or to be delivered to the carrier,
the transfer block includes: a substrate handling mechanism that takes out or stores a plurality of substrates from and into the carrier placed in the carrier placing shelf, as a batch; and
a first orientation converting mechanism that converts the plurality of substrates in the horizontal orientation to a vertical orientation,
the processing block includes: a batch processing area extending in a direction separating from the transfer block;
a single-wafer processing area having one end at a position near the transfer block and another end extending in the direction separating from the transfer block;
a single-wafer transporting area interposed between the batch processing area and the single-wafer processing area, and having one end positioned adjacently to the transfer block and another end extending in the direction separating from the transfer block; and
a batch substrate transporting area provided along the batch processing area, and having one end extending to the transfer block and another end extending in the direction separating from the transfer block,
the batch processing area is provided with a plurality of batch processing baths that are configured to immerse a plurality of substrate as a batch, and that are arranged along a direction in which the batch processing area extends; and a second orientation converting mechanism that is configured to convert the plurality of substrates from the vertical orientation to the horizontal orientation,
the single-wafer processing area is provided with a single-wafer processing chamber configured to process one substrate at a time, along the direction in which the single-wafer processing area extends,
the single-wafer transporting area is provided with a single-wafer transporting mechanism that is configured to transport a substrate to and from the second orientation converting mechanism, the single-wafer processing chamber, and the substrate placing unit,
the batch substrate transporting area is provided with a batch substrate transporting mechanism configured to transport a plurality of substrates to and from a substrate delivery position defined in the transfer block, the plurality of batch processing baths, and the second orientation converting mechanism, as a batch, and
the substrate handling mechanism in the transfer block is configured to transport a plurality of substrates to the first orientation converting mechanism, as a batch, and transport a plurality of substrates from the substrate placing unit, as a batch.

2. The substrate processing apparatus according to claim 1, wherein
the second orientation converting mechanism is provided on an opposite side of the transfer block, with the plurality of batch processing baths disposed between the transfer block and the second orientation converting mechanism.

3. The substrate processing apparatus according to claim 1, wherein
the second orientation converting mechanism is provided between two batch processing baths among the plurality of batch processing baths.

4. The substrate processing apparatus according to claim 1, wherein
the second orientation converting mechanism is provided between the transfer block and the plurality of batch processing baths.

5. The substrate processing apparatus according to claim 1, wherein
the substrate placing unit is provided in a manner fixed at any one of a boundary between the transfer block and the single-wafer transporting area, in the transfer block, and in the single-wafer transporting area.

6. The substrate processing apparatus according to claim 1, further comprising:
a placing unit moving mechanism, wherein
the substrate placing unit is provided movably in the single-wafer transporting area, and
the placing unit moving mechanism moves the substrate placing unit in a direction in which the single-wafer transporting area extends.

7. The substrate processing apparatus according to claim 6, wherein
the placing unit moving mechanism moves the substrate placing unit in the direction in which the single-wafer transporting area extends, in a manner following the single-wafer transporting mechanism.

8. The substrate processing apparatus according to claim 1, wherein
the single-wafer transporting mechanism includes a mechanism main unit and an upper rail provided above the single-wafer transporting area and along the single-wafer transporting area, and
the mechanism main unit is suspended from the upper rail and is configured to move along the upper rail.

9. The substrate processing apparatus according to claim 1, wherein
the second orientation converting mechanism includes: a substrate holding unit that holds the plurality of substrates in the vertical orientation transported by the batch substrate transporting mechanism;
a substrate extracting mechanism capable of extracting two or more substrates from the plurality of substrates held by the substrate holding unit; and
an orientation converting unit that converts an orientation of the two or more substrates extracted by the substrate extracting mechanism from the vertical orientation to the horizontal orientation as a batch.
